(19) United States
(12) Patent Application Publication
(10) Pub. No.: US 2026/0153321 A1
(43) Pub. Date: Jun. 4, 2026

(54) POSITION DETECTION SENSOR

(71) Applicant: Keyence Corporation, Osaka (JP)

(72) Inventors: Hiroki MATSUI, Osaka (JP); Akinori NAGATA, Osaka (JP)

(73) Assignee: Keyence Corporation, Osaka (JP)

(21) Appl. No.: 19/373,808

(22) Filed: Oct. 30, 2025

(30) Foreign Application Priority Data
Dec. 3, 2024 (JP) 2024-210016

(51) Int. Cl. G01B 7/00; G01D 5/14; G01R 33/00; G01R 33/07

(52) U.S. Cl. CPC G01B 7/003; G01D 5/145; G01R 33/0005; G01R 33/0094; G01R 33/072

(57) ABSTRACT

To facilitate installation work of a position detection sensor. A detection device generates a detection signal according to a position of a magnet provided on a displacement body. A specification unit specifies a position of the displacement body in the first direction on the basis of the detection signal generated by the detection device. A determination unit generates determination information on the basis of the position of the displacement body and detection ranges set in advance. A setting unit is capable of adjusting positions of the first region and the second region set as the detection ranges, and adjusts at least one of the number or a width of the detection ranges.

### CROSS-REFERENCE TO RELATED APPLICATIONS

The present application claims foreign priority based on Japanese Patent Application No. 2024-210016, filed Dec. 3, 2024, the contents of which are incorporated herein by reference.

### BACKGROUND OF THE INVENTION

### 1. Technical Field

The present invention relates to a position detection sensor.

### 2. Description of the Related Art

In factory automation, an air cylinder is used to realize operations such as pushing, pulling, and grasping. JP2003-240531A proposes detection of a position of a piston moving in an air cylinder by air pressure or hydraulic pressure.

Moreover, JP2003-240531A proposes a display unit that emits light when the piston reaches a predetermined position.

However, in the invention described in JP2003-240531A, it is only known that the piston has reached the predetermined position. Generally, the piston moves in a movement section from a movement start position to a movement end position. Therefore, it would be convenient to be able to specifically indicate where the piston is located in the movement section. In particular, it becomes easy to install a position detection sensor that detects the position of the piston in the cylinder. Therefore, an object of the present invention is to facilitate installation work of a position detection sensor.

### SUMMARY OF THE INVENTION

The present invention provides, for example, a position detection sensor configured to detect a position of a displacement body movable in parallel with a first direction, the position detection sensor including:
a detection device configured to generate a detection signal according to a position of a magnet provided on the displacement body;
a position specification unit configured to specify a position of the displacement body in the first direction on the basis of the detection signal generated by the detection device;
a determination unit configured to generate determination information on the basis of a position of the displacement body along the first direction specified by the position specification unit and detection ranges set in advance; and
a setting unit configured to be able to adjust positions of a first region and a second region set as the detection ranges and be able to adjust at least one of a number or a width of the detection ranges.

According to the present invention, installation work of the position detection sensor is facilitated.

### BRIEF DESCRIPTION OF THE DRAWINGS

FIG. 1 is a diagram for explaining a position detection sensor;

FIG. 2 is a perspective view for explaining a cylinder sensor and a cylinder;

FIG. 3 is an exploded perspective view of the cylinder sensor;

FIG. 4 is a schematic cross-sectional view of the cylinder sensor and the cylinder;

FIG. 5 is a diagram illustrating a control system of the cylinder sensor;

FIG. 6 is a diagram illustrating a control system of a relay amplifier;

FIGS. 7A to 7C are diagrams for explaining symbols;

FIGS. 8A to 8C are diagrams for explaining symbols;

FIG. 9 is a flowchart illustrating a display control method;

FIGS. 10A to 10C are diagrams for explaining symbols;

FIGS. 11A to 11C are diagrams for explaining symbols;

FIG. 12 is a flowchart illustrating a setting method;

FIG. 13 is a flowchart illustrating a deletion method;

FIGS. 14A and 14B are diagrams for explaining symbols;

FIG. 15 is a diagram for explaining a user interface in the relay amplifier;

FIGS. 16A and 16B are diagrams illustrating another example of symbols;

FIG. 17 is a diagram illustrating another example of a symbol;

FIG. 18 is a diagram illustrating another example of a symbol;

FIGS. 19A to 19C are diagrams for explaining symbols displayed on the relay amplifier or a display panel;

FIGS. 20A to 20C are diagrams for explaining symbols displayed on the relay amplifier or the display panel;

FIGS. 21A to 21C are diagrams for explaining symbols displayed on the relay amplifier or the display panel;

FIG. 22 is a flowchart illustrating a display control method in the relay amplifier;

FIG. 23 is a flowchart illustrating a setting method in the relay amplifier;

FIG. 24 is a flowchart illustrating a deletion method in the relay amplifier;

FIG. 25 is a diagram for explaining the display panel;

FIG. 26 is a diagram for explaining a symbol displayed on the display panel;

FIGS. 27A to 27C are diagrams for explaining symbols displayed on the display panel;

FIG. 28 is a diagram for explaining a symbol displayed on the display panel;

FIG. 29 is a diagram for explaining a symbol displayed on the display panel;

FIG. 30 is a flowchart illustrating a display control method in the display panel;

FIG. 31 is a flowchart illustrating a setting method in the display panel;

FIG. 32 is a diagram illustrating an operation screen in the relay amplifier;

FIG. 33 is a diagram for explaining transition of a setting screen in the relay amplifier;

FIG. 34 is a diagram for explaining transition of the setting screen in the relay amplifier;

FIG. 35 is a diagram for explaining transition of the setting screen in the relay amplifier;

FIG. 36 is a diagram for explaining transition of the setting screen in the relay amplifier;

FIG. 37 is a diagram for explaining transition of the setting screen in the relay amplifier;

FIG. 38 is a flowchart illustrating a setting method in the relay amplifier;

FIG. 39 is a diagram illustrating another example of the control system of the cylinder sensor;

FIGS. 40A and 40B are diagrams for explaining another example of the position detection sensor; and

FIG. 41 is a diagram illustrating another example of the control system of the relay amplifier.

### DETAILED DESCRIPTION

Hereinafter, embodiments will be described in detail with reference to the accompanying drawings. Note that the following embodiments do not limit the invention according to the claims, and all combinations of features described in the embodiments are not necessarily essential to the invention. Two or more features of the plurality of features described in the embodiment may be arbitrarily combined. Furthermore, the same or similar configurations are denoted by the same reference numerals, and redundant description will be omitted.

### 1. Position Detection Sensor

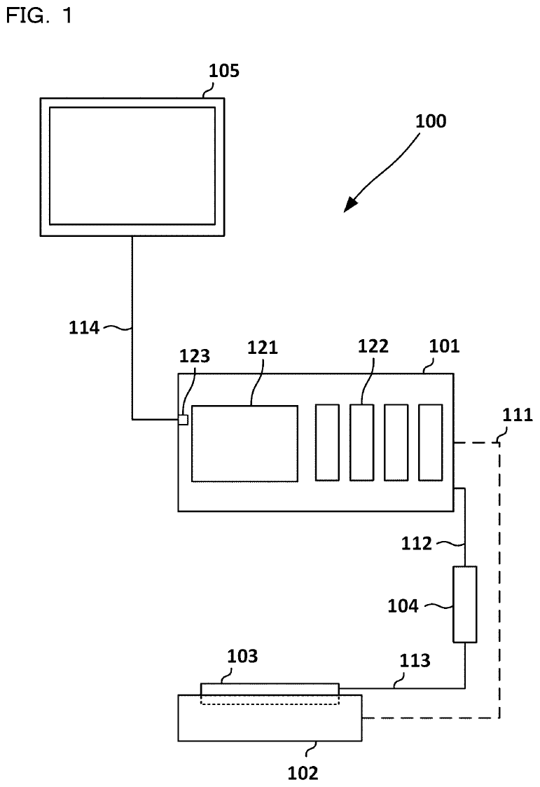

FIG. 1 illustrates a position detection sensor 100. The valve system 101 includes one or a plurality of valves 122 connected to the air cylinder 102 via an air tube 111, and a controller 121 that controls the valves 122. The controller 121 communicates with the relay amplifier 104 via an IO-Link cable 112. The IO-Link is merely an example of the communication standard, and other communication standards may be adopted. The relay amplifier 104 is a relay apparatus that relays a detection result of a cylinder sensor 103 to the controller 121 and relays power supplied from the valve system 101 to the cylinder sensor 103. The relay amplifier 104 does not need to have a signal amplification function. The relay amplifier 104 communicates with the cylinder sensor 103 via an IO-Link cable 113. The cylinder sensor 103 detects a position of a piston movably provided in the air cylinder 102, and outputs a detection result to the relay amplifier 104. The relay amplifier 104 outputs a detection result of the cylinder sensor 103 to the controller 121. As a result, the controller 121 recognizes the position of the piston and controls the amount of air supplied to the air cylinder 102 by the valve 122 according to the position of the piston.

The position detection sensor 100 may optionally include a display panel 105. At a work site (factory) where the position detection sensor 100 is installed, it may be required to display a detection result of the position detection sensor 100 on a larger screen. This is to enable a user located at a position away from the air cylinder 102 to visually recognize the detection result. Alternatively, this is because the display area of the display function of the air cylinder 102 is smaller than the display area of the display panel 105. The controller 121 of the valve system 101 and the display panel 105 are connected by an Ethernet (registered trademark) cable 114, and various signals are transmitted and received. In particular, the valve system 101 has a dedicated communication port 123 to which the display panel 105 is connected, and the display panel 105 is connected to the dedicated communication port 123.

The cylinder sensor 103 is positioned with respect to the air cylinder 102 as desired by the user. An indication may be provided to the user to facilitate installation of the cylinder sensor 103 by the user.

The cylinder sensor 103 and the relay amplifier 104 may be integrated. On the other hand, it may be separated into the cylinder sensor 103 (sensor head) and the relay amplifier 104 (main body). As a result, for example, the sensor head may be downsized. As a result, the cylinder sensor 103 can be installed even in the air cylinder 102 having a small mounting margin.

### 2. Arrangement of Cylinder Sensor and Air Cylinder

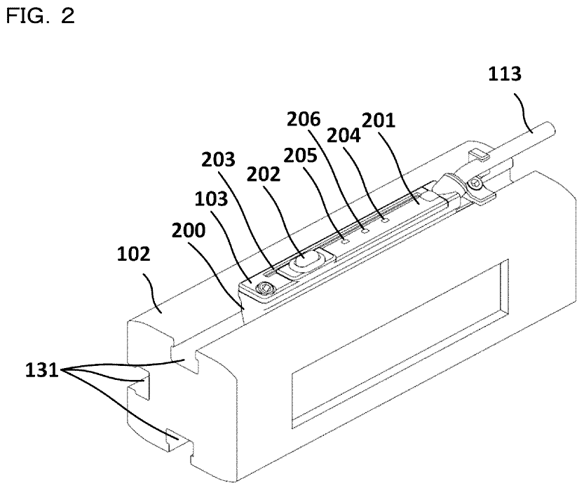

FIG. 2 illustrates a state in which the cylinder sensor 103 is installed in the air cylinder 102. According to this example, the air cylinder 102 includes one or more grooves 131 extending along the longitudinal direction of the air cylinder 102. The cylinder sensor 103 is inserted into and fixed to any one groove 131 of the one or more grooves 131. Here, the external dimension of the housing 200 of the cylinder sensor 103 is slightly smaller than the dimension of the inner space of the groove 131. Thus, the cylinder sensor 103 can slide in the groove 131. Note that the cylinder sensor 103 can also be installed in the cylinder 102 that does not include the groove 131. In this case, the cylinder sensor 103 may be fixed to the cylinder 102 using a band and a fitting.

A cover 201 having translucency is provided on an upper portion of the housing 200. A power supply LED 204 indicating on/off of the power supply, a first output LED 205 indicating that the first output signal is output, and a second output LED 206 indicating that the second output signal is output are disposed below the cover 201. The LED is an abbreviation for a light emitting diode. What detection result is assigned to the first output signal and the second output signal can be set by a user. For example, when it is detected that the position of the piston of the air cylinder 102 is included in the first detection range, the level of the first output signal may change from low to high. When it is detected that the position of the piston of the air cylinder 102 is included in the second detection range, the level of the second output signal may change from low to high.

The operation button 202 is used by the user to perform various settings on the cylinder sensor 103.

The display window 203 displays a symbol indicating the position of the piston in the air cylinder 102. Here, the symbol may be realized by turning on the LED corresponding to the position of the piston. The symbol may be a bar indicating the position of the piston or a bar indicating the travel distance of the piston from the reference position. The LED is merely an example, and a liquid crystal display, an organic EL display (OLED display), or the like may be adopted. EL is an abbreviation for electroluminescence. The OLED is an abbreviation of an organic light emitting diode. In this case, the symbol may be a numerical value or a combination of an image (example: a bar) and a numerical value. Moreover, the LED and the display may be combined.

### 3. Structure of Cylinder Sensor

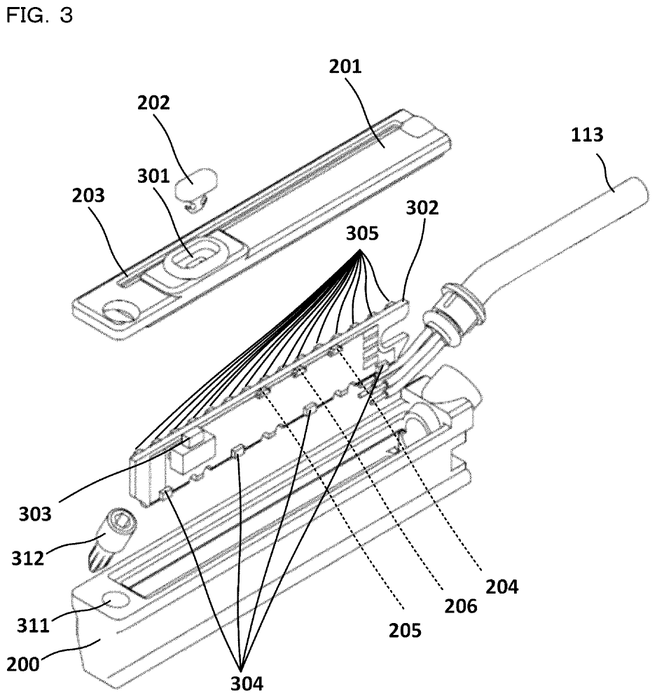

FIG. 3 is an exploded perspective view of the cylinder sensor 103. The cover 201 is provided with a housing hole 301 for housing the operation button 202. A control board 302 is fixed inside the housing 200. The control board 302 is provided with an operation switch 303. The operation switch 303 may be, for example, a tact switch or the like in which when pressed by the operation button 202, a movable contact comes into contact with a fixed contact and conducts.

The control board 302 further includes a plurality of LEDs 305 disposed below the display window 203. The plurality of LEDs 305 may be arranged at predetermined constant intervals (example: 2 mm). The plurality of LEDs 305 displays symbols indicating position detection results. The plurality of LEDs 305 may be an RGB LED capable of displaying information in colors processed by a red light emitting element, a green light emitting element, and a blue light emitting element. The plurality of LEDs 305 may simultaneously display a symbol indicating the first detection range corresponding to the first output signal, a symbol indicating the second detection range corresponding to the second output signal, and a symbol indicating the current position of the piston. For example, the plurality of LEDs 305 corresponding to the first detection range may be turned on in blue, the plurality of LEDs 305 corresponding to the second detection range may be turned on in orange, and one or the plurality of LEDs 305 corresponding to the current position of the piston may be turned on in green. Note that, when the piston enters the first detection range, the LED 305 corresponding to the current position of the piston may be turned on in another color (examples: white, red, yellow, green blinking, blue blinking).

A plurality of Hall elements 304 is disposed in a side surface region close to the bottom surface among the side surfaces of the control board 302. The plurality of Hall elements 304 is an example of a magnetic detection element that detects a change in magnetic flux density received from a magnet built in the piston and outputs a detection signal. The plurality of Hall elements 304 is disposed at predetermined constant intervals (example: 4 mm or more and 6 mm or less). As described above, the arrangement interval of the plurality of Hall elements 304 is larger than the arrangement interval of the plurality of LEDs 305. The arrangement interval of the plurality of Hall elements 304 may be about 10 mm. That the arrangement interval of the plurality of Hall elements 304 is larger than the arrangement interval of the plurality of LEDs 305 is merely an example, and this condition is not essential.

An upper surface of the housing 200 includes a screw hole 311. A fixing screw 312 is screwed into the screw hole 311. The tip of the fixing screw 312 protrudes from the side surface of the housing 200 and presses the groove 131 of the air cylinder 102. As a result, the cylinder sensor 103 is firmly fixed in the groove 131 of the air cylinder 102. Note that, when the fixing screw 312 is loosened, the cylinder sensor 103 can freely slide in the groove 131.

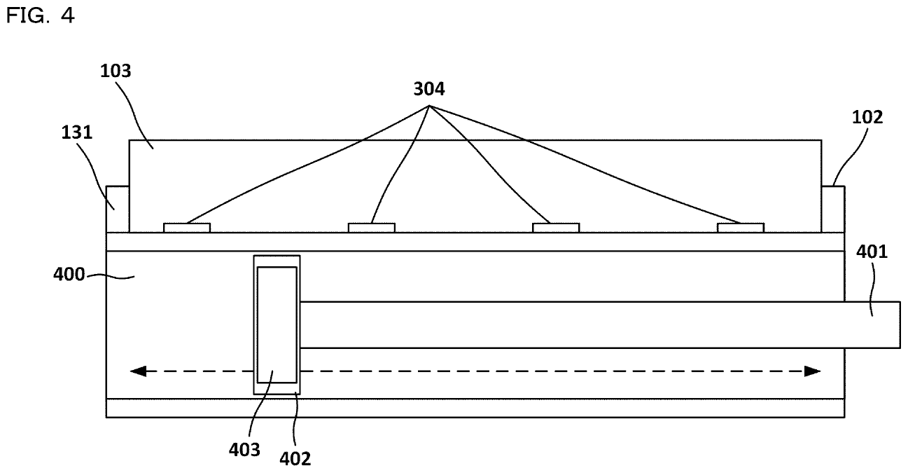

FIG. 4 is a schematic cross-sectional view illustrating the air cylinder 102 and the cylinder sensor 103. The air cylinder 102 includes a cylinder tube 400 disposed below the groove 131, a piston 402 slidable in the cylinder tube 400, a magnet 403 provided on the piston 402, and a piston rod 401. The piston 402 moves in conjunction with extrusion or suction of air by the valve system 101, thereby moving the piston rod 401. The piston rod 401 may operate a robot hand (gripper) or the like.

The cylinder sensor 103 calculates the position of the piston 402 on the basis of the respective detection results output from the plurality of Hall elements 304, and controls turning on and off of each of the plurality of LEDs 305, the first output LED 205, and the second output LED 206 on the basis of the calculation result. The control of turning on may include lighting color control.

### 4. Control System

### 4-1. Cylinder Sensor

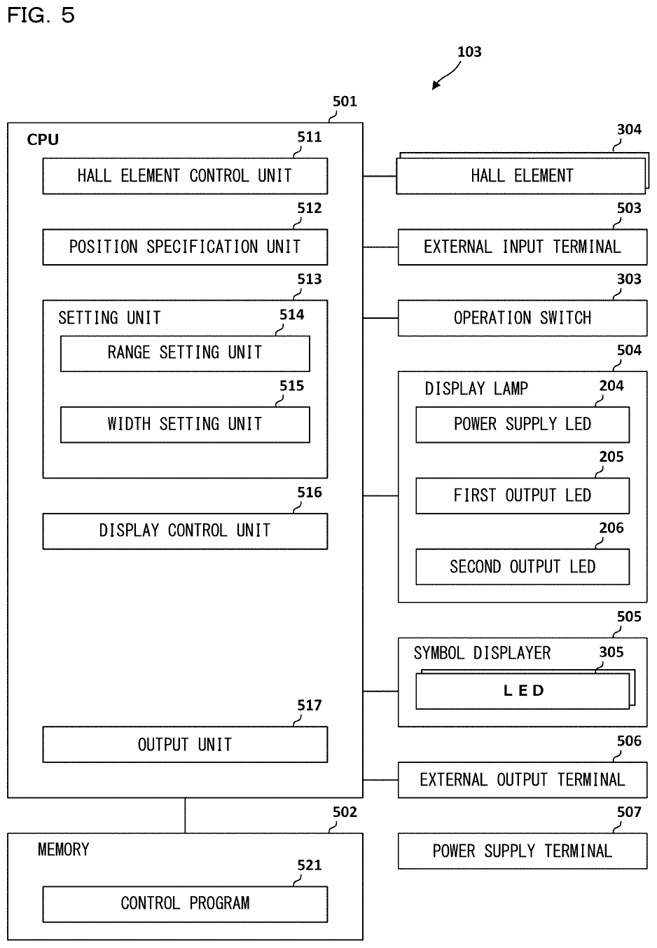

FIG. 5 illustrates a controller of the cylinder sensor 103. The CPU 501 is a processor or a processing circuit that realizes various functions by executing a control program 521 stored in a memory 502. One or more of the plurality of functions described below may be mounted on an integrated circuit provided outside the CPU 501. A drive circuit that generates a drive current for driving the load is provided between the CPU 501 and the load, but the description of the drive circuit is omitted in FIG. 5. A Hall element control unit 511 supplies power to the plurality of Hall elements 304 as an example of a magnetic detection element, and acquires detection signals output from the plurality of Hall elements 304. A position specification unit 512 specifies the position of the piston 402 on the basis of the detection signals output from the plurality of Hall elements 304.

A setting unit 513 executes various settings necessary for the valve system 101 to use the detection result of the cylinder sensor 103. A range setting unit 514 sets the position of the i-th detection range corresponding to the i-th output signal. i is an integer of 1 or more. For example, the start position and the end position of the i-th detection range may be set. Alternatively, one of the start position and the end position of the i-th detection range and the width of the i-th detection range may be set. Hereinafter, i is 1 or 2, but i may be 3 or more. A width setting unit 515 sets a width of the i-th detection range. The setting unit 513 may set the cylinder sensor 103 according to a setting instruction input from the relay amplifier 104, the valve system 101, or the display panel 105 through an external input terminal 503. The setting unit 513 may execute various settings according to a predetermined operation (examples: long press operation for predetermined seconds, short press operation, double click) on the operation switch 303.

A display control unit 516 controls a display lamp 504 and a symbol displayer 505 to display various types of information to the user. For example, when power is supplied through a power supply terminal 507 connected to the power line included in the IO-Link cable 113 and the CPU 501 is activated, the display control unit 516 turns on the power supply LED 204. In a case where the position of the piston 402 specified by the position specification unit 512 is included in the first detection range, the display control unit 516 turns on the first output LED 205. In a case where the position of the piston 402 specified by the position specification unit 512 is included in the second detection range, the display control unit 516 turns on the second output LED 206. The display control unit 516 turns on one or a plurality of LEDs 305 corresponding to the first detection range. The display control unit 516 turns on one or a plurality of LEDs 305 corresponding to the second detection range. The display control unit 516 turns on one or a plurality of LEDs 305 corresponding to the third detection range. As described above, the display control unit 516 turns on one or a plurality of LEDs 305 corresponding to the i-th detection range.

An output unit 517 outputs position information indicating the position of the piston 402 specified by the position specification unit 512 to the relay amplifier 104 through an external output terminal 506 and the IO-Link cable 113. Here, the information output from the output unit 517 can include at least one of the following information.
Position information of the piston 402 of the air cylinder 102 . . . Information indicating the position of the piston 402 inside the air cylinder 102. The position information may include a distance from the predetermined reference point to the current position of the piston 402.
The operation speed of the air cylinder 102 . . . It is the operation speed of the piston 402. Unit information designating a unit (examples: mm/sec, m/sec, in/sec, ft/sec) of the operation speed may be included.
Acceleration . . . Acceleration of the piston 402. This information is included in a case where the cylinder sensor 103 can detect the acceleration of the piston 402. Unit information designating a unit (examples: mm/s², m/s²) of the acceleration may be included.
Output information . . . Information indicating whether the piston 402 exists within a detection range of the position of the piston 402 set when the cylinder sensor 103 is installed with respect to the air cylinder 102. This may be an output signal that is output only in a case where the piston 402 is within the detection range.
Positional deviation detection situation . . . Information output in a case where the piston 402 is stopped outside the detection range.
Model specific information such as a body state, a model . . . A length of the cylinder sensor 103, and a slot type.
Error . . . Information indicating damage or the like of the cylinder sensor 103.
Setting parameters (memory internal information) . . . Setting information such as an output position, an output width (range in which the output signal is turned on), a span (inclination of an actual movement distance with respect to a movement distance of the piston 402/mainly used in a chuck or the like), an offset (an arbitrary position is set to 0), an installation direction (in which direction the cylinder sensor 103 is installed, up, down, left, and right), NPN/PNP (output polarity), and a unit (examples: mm, mm, inch, foot, etc.).

Note that the CPU 501 may receive the following information from the relay amplifier 104.
Setting parameters such as teaching (setting of output position), span (inclination of actual movement distance with respect to movement distance of piston 402/mainly used in chuck or the like), offset (any position is set to 0), installation direction (in which direction cylinder sensor 103 is installed, up, down, left, and right), output position, NPN/PNP (output polarity), output logic (whether the contact is closed or opened when ON), unit (examples: mm, m, inch, foot), and the like.
Instruction information such as communication synchronization (communication synchronization signal), output set (output position setting signal), and shipment reset (initialization).
Error . . . Error information transmitted to the cylinder sensor 103 in a case where an abnormal state of the valve system 101 or the air cylinder 102 itself is detected for the attached air cylinder 102.

In a case where the position of the piston 402 is included in the first detection range, the output unit 517 outputs the first output signal. In a case where the position of the piston 402 is included in the second detection range, the output unit 517 outputs the second output signal. In a case where the position of the piston 402 is included in the third detection range, the output unit 517 outputs the third output signal. As described above, in a case where the position of the piston 402 is included in the i-th detection range, the output unit 517 outputs the i-th output signal. Here, outputting the output signal may be changing the logic of the output signal in accordance with a predetermined rule.

The memory 502 is a storage apparatus including a storage element such as a random access memory (RAM) and a non-volatile storage element such as a read-only memory (ROM).

### 4-2. Relay Amplifier

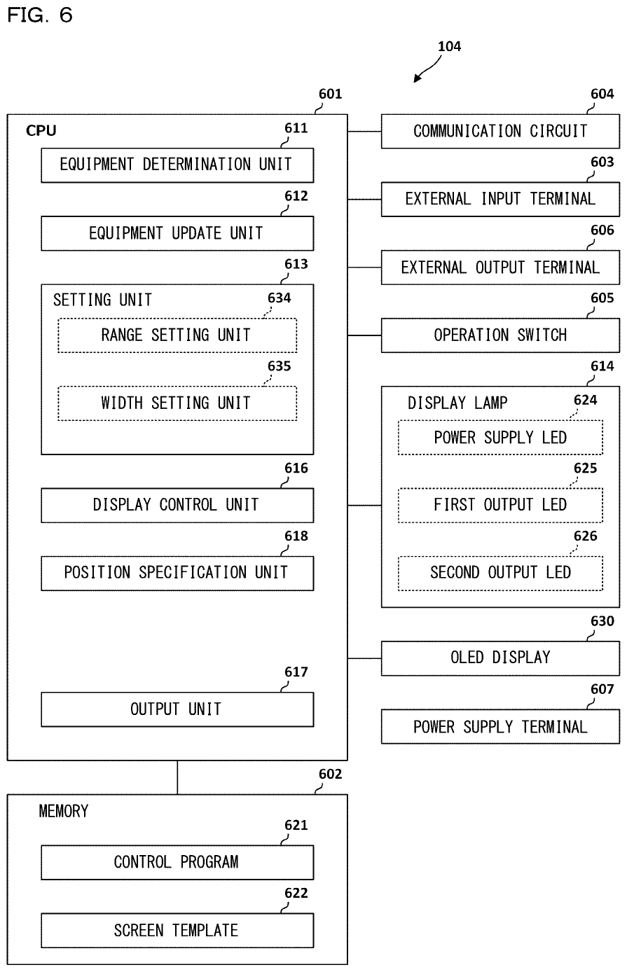

FIG. 6 illustrates a controller of the relay amplifier 104. The CPU 601 is a processor or a processing circuit that realizes various functions by executing the control program 621 stored in the memory 602. Note that one or more of the plurality of functions described below may be mounted on an integrated circuit provided outside the CPU 601.

The communication circuit 604 is a circuit that communicates with the valve system 101 via the IO-Link cable 112 and communicates with the cylinder sensor 103 via the IO-Link cable 113. The power supply terminal 607 is supplied with power from the valve system 101 via the IO-Link cable 112 or supplies power to the cylinder sensor 103 via the IO-Link cable 113. The external input terminal 603 includes a terminal to which the IO-Link cable 112 is connected and a terminal to which the IO-Link cable 113 is connected, and is a terminal for receiving information transmitted from the cylinder sensor 103 and the valve system 101. The external output terminal 606 includes a terminal to which the IO-Link cable 112 is connected and a terminal to which the IO-Link cable 113 is connected, and is a terminal for transmitting information to the cylinder sensor 103 and the valve system 101.

An operation switch 605 is one or more switches for receiving various operation inputs by the user. A display lamp 614 is an LED that displays a detection state of the cylinder sensor 103. The display lamp 614 may include a power supply LED 624 indicating whether the relay amplifier 104 is turned on or off, a first output LED 625 indicating whether the first output signal is output from the cylinder sensor 103, and a second output LED 626 indicating whether the second output signal is output from the cylinder sensor 103.

The OLED display 630 is a display including an organic EL light emitting diode. The memory 602 is a storage apparatus including a storage element such as a random access memory (RAM) and a non-volatile storage element such as a read-only memory (ROM).

The functions implemented by the CPU 601 include the following functions. The equipment determination unit 611 communicates with equipment (the valve system 101 and the cylinder sensor 103) connected to the relay amplifier 104 to specifically specify the equipment. The equipment update unit 612 updates setting information and the control program 521 of equipment (example: the cylinder sensor 103) connected to the relay amplifier 104.

The setting unit 613 sets the operation of the relay amplifier 104. Moreover, the setting unit 613 may set the cylinder sensor 103 instead of the setting unit 513 or in cooperation with the setting unit 513. For example, the range setting unit 634 sets the position of the detection range of the piston 402 in the cylinder sensor 103. The width setting unit 635 sets the width of the detection range of the piston 402 in the cylinder sensor 103. The range setting unit 634 and the width setting unit 635 may operate in a case where the cylinder sensor 103 does not include the symbol displayer 505. In this case, the OLED display 630 functions as the symbol displayer 505.

A display control unit 616 controls turning on and off of a display lamp 614 and displays information on the OLED display 630. For example, the display control unit 616 may cause the OLED display 630 to display a position symbol indicating the position of the piston 402 according to the position information of the piston 402 output from the cylinder sensor 103. Moreover, the display control unit 616 may display a range symbol indicating the detection range on the OLED display 630 on the basis of range information indicating the detection range of the piston 402. The position symbol and the range symbol may be displayed in conjunction with both the cylinder sensor 103 and the relay amplifier 104. This is because the relay amplifier 104 can obtain the position information of the piston 402 and the range information of the detection range from the cylinder sensor 103.

The output unit 617 generates an output signal corresponding to the detection result received from the cylinder sensor 103, and outputs the output signal to the valve system 101. The output unit 617 may transfer various information received from the cylinder sensor 103 to the valve system 101.

### 5. Teaching (Installation Work of Cylinder Sensor)

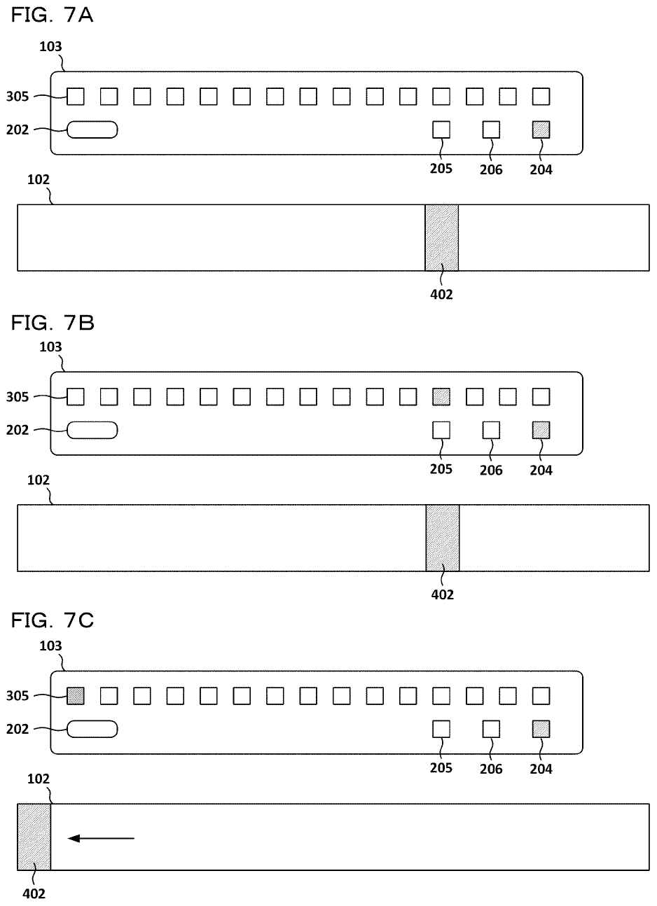

FIG. 7A illustrates a display state when power is supplied from the outside to the cylinder sensor 103 and the cylinder sensor 103 is activated. The power supply LED 204 indicates that power is supplied to the cylinder sensor 103 (power ON state). Note that the plurality of LEDs 305 may display a symbol indicating that it is immediately after the power is turned on. For example, the plurality of LEDs 305 may be controlled such that the LEDs 305 to be turned on are switched in order. As a result, light may be output like a wave moving from right to left. Note that the plurality of LEDs 305 may continuously display a symbol indicating that it is immediately after the power is turned on until the position specification unit 512 can specify the position of the piston 402. Alternatively, the plurality of LEDs 305 may be simultaneously turned off after the symbol is displayed for a certain period.

FIG. 7B illustrates a state in which the position specification unit 512 specifies the position of the piston 402. Among the plurality of LEDs 305, only the LED 305 corresponding to the position of the piston 402 is turned on. Here, the LED 305 may be turned on in a first color (example: green). Note that, when the user moves the cylinder sensor 103 relative to the air cylinder 102, the plurality of LEDs 305 is turned on or off so as to follow the position of the piston 402. That is, only the LED 305 corresponding to the position of the piston 402 may be turned on. Note that all the LEDs 305 existing to the right of the position of the piston 402 may be turned on. Alternatively, all the LEDs 305 existing to the left of the position of the piston 402 may be turned on. As a result, the position of the piston 402 may be displayed by a bar symbol.

FIG. 7C illustrates a symbol in a case where the LED 305 corresponding to the position of the piston 402 specified by the position specification unit 512 does not exist or in a case where the piston 402 exists outside the detectable range of the cylinder sensor 103. In this example, since there is no LED 305 corresponding to the position of the piston 402, only the leftmost LED 305 located at the outermost side among the plurality of LEDs 305 may be turned on. The leftmost LED 305 may be turned on in a second color (example: red) or blink in a first or second color to suggest the presence of the piston 402 outside of the detectable range.

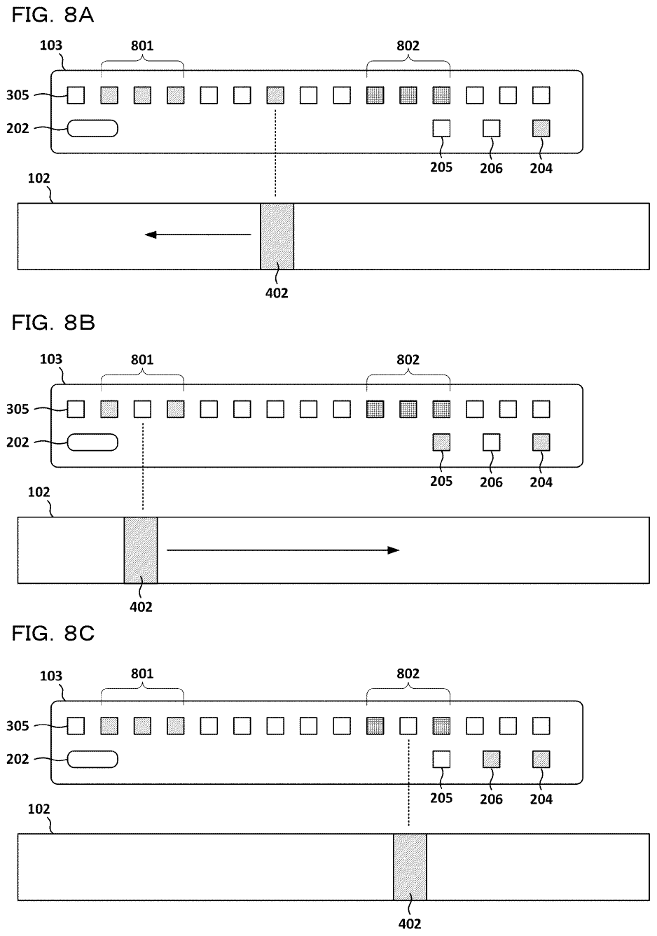

FIG. 8A illustrates a symbol in a case where the first detection range 801 and the second detection range 802 have been set by teaching. In this example, three LEDs 305 are allocated to each of the first detection range 801 and the second detection range 802 among the plurality of LEDs 305. The three LEDs 305 allocated to the first detection range 801 may indicate the position and width of the first detection range 801 by being turned on in a third color (example: blue), for example. The three LEDs 305 allocated to the second detection range 802 may indicate the position and width of the second detection range 802 by being turned on in a fourth color (example: orange), for example.

In FIG. 8A, the piston 402 exists in an intermediate range existing between the first detection range 801 and the second detection range 802. Therefore, among the plurality of LEDs 305 existing in the intermediate range, only one LED 305 corresponding to the position of the piston 402 is turned on. Here, the LED 305 may be turned on in the first color (example: green).

FIG. 8B illustrates a symbol in a case where the piston 402 exists in the first detection range 801. In this example, the piston 402 is located at the center of the first detection range 801. Therefore, among the three LEDs 305 corresponding to the first detection range 801, the central LED 305 is turned on in a color (example: white) different from the lighting colors of the remaining two LEDs 305. As described above, the color indicating the first detection range 801 is different from the color indicating the position of the piston 402, so that the user can clearly recognize the position of the piston 402. Note that, in a case where the piston 402 exists in the first detection range 801, the LED 305 corresponding to the position of the piston 402 may blink. In the case of blinking in this manner, the lighting color of the LED 305 corresponding to the position of the piston 402 and the lighting colors of the remaining two LEDs 305 may be different from each other or may be the same color.

According to FIG. 8B, moreover, the first output LED 205 is turned on. This indicates that the position of the piston 402 is included in the first detection range 801 and that the first output signal is output (that the first output signal is high). The logic (High/Low) of the output signal can be set by the user. Therefore, the logic of the output signal depends on the user setting.

FIG. 8C illustrates a symbol in a case where the piston 402 exists in the second detection range 802. According to this example, the piston 402 is located at the center of the second detection range 802. Therefore, among the three LEDs 305 corresponding to the second detection range 802, the central LED 305 is turned on in a color (example: white) different from the lighting colors of the remaining two LEDs 305. As described above, the color indicating the second detection range 802 is different from the color indicating the position of the piston 402, so that the user can clearly recognize the position of the piston 402. Note that, in a case where the piston 402 exists in the second detection range 802, the LED 305 corresponding to the position of the piston 402 may blink. In the case of blinking in this manner, the lighting color of the LED 305 corresponding to the position of the piston 402 and the lighting colors of the remaining two LEDs 305 may be different from each other or may be the same color.

According to FIG. 8C, moreover, the second output LED 206 is turned on. This indicates that the position of the piston 402 is included in the second detection range 802 and that the second output signal is output (that the second output signal is high).

Here, the first output LED 205 and the second output LED 206 are exemplified, but third, fourth, . . . output LEDs may be mounted.

### 6. Flowchart of Display Control Method

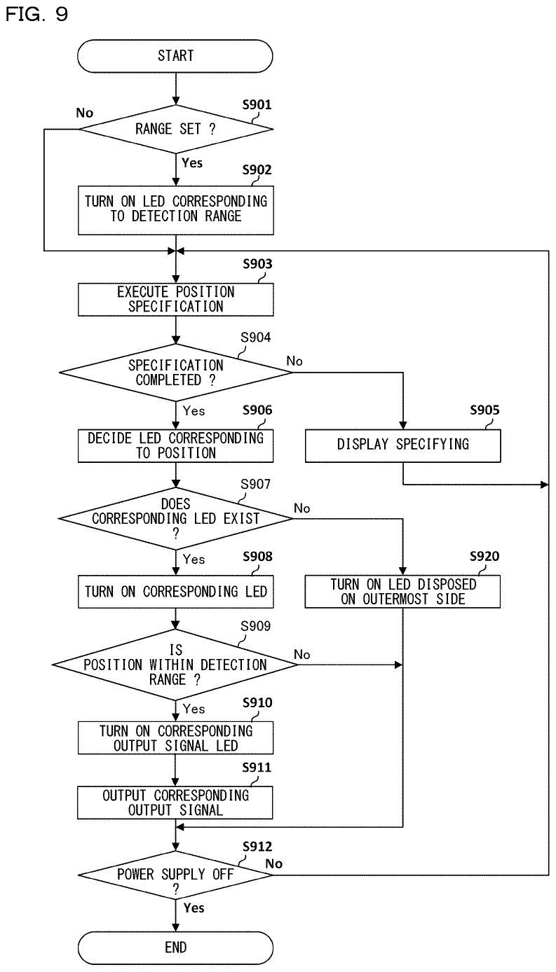

FIG. 9 illustrates a display control method executed by the CPU 501 of the cylinder sensor 103 in accordance with the control program 521. When power is supplied from the relay amplifier 104 to activate the CPU 501, the following processing is executed.

In S901, the CPU 501 (display control unit 516) refers to the setting information stored in the memory 502, and determines whether one or more detection ranges are set. When one or more detection ranges are not set, the CPU 501 skips S902 and proceeds to S903. When one or more detection ranges are set, the CPU 501 proceeds to S902.

In S902, the CPU 501 (display control unit 516) turns on the LED 305 corresponding to the detection range. A table indicating a relationship between the detection range and the identification information of the LED 305 may be stored in the memory 502. Identification numbers may be assigned to the N LEDs 305 in ascending order from the LED 305 located on the right to the LED 305 located on the left. In this case, the identification information of the LED 305 may be the identification numbers. The setting information may include color information indicating a lighting color of the LED 305 corresponding to the i-th detection range. In accordance with the color information, the CPU 501 turns on the Mi LEDs 305 corresponding to the i-th detection range in the color corresponding to the color information. Mi is a variable indicating the width of the i-th detection range, and corresponds to the number of LEDs 305 to be turned on.

In S903, the CPU 501 (position specification unit 512) executes position calculation for specifying the position of the piston 402 on the basis of the detection results of the plurality of Hall elements 304. The position calculation may be a calculation for specifying a position corresponding to the Hall element 304 that outputs the largest detection signal among the plurality of Hall elements 304. Alternatively, the position of the piston 402 may be calculated by executing weighting calculation or interpolation calculation on the magnitudes of the detection signals output from the plurality of Hall elements 304. In the latter case, the position is identified with finer accuracy.

In S904, the CPU 501 (position specification unit 512 or display control unit 516) determines whether the position of the piston 402 has been specified. For example, in a case where the cylinder sensor 103 is not attached to the air cylinder 102, the position calculation fails. On the other hand, in a case where the cylinder sensor 103 is correctly attached to the air cylinder 102, the position calculation is successful. In a case where the position of the piston 402 has not been specified, the CPU 501 proceeds to S905. In S905, the CPU 501 (display control unit 516) displays a symbol indicating that the position is being specified using the plurality of LEDs 305. Thereafter, the CPU 501 returns from S905 to S903, and continues the position calculation. On the other hand, in a case where the position of the piston 402 has been specified, the CPU 501 proceeds to S906.

In S906, the CPU 501 (position specification unit 512 or display control unit 516) decides the LED 305 corresponding to the position of the piston 402. The memory 502 stores a table indicating a correspondence relationship between the position of the piston 402 and the identification number of the LED 305. The CPU 501 refers to this table to specify the identification number of the LED 305 corresponding to the position of the piston 402.

In S907, the CPU 501 (position specification unit 512 or display control unit 516) determines whether the LED 305 corresponding to the position of the piston 402 exists. In a case where the LED 305 corresponding to the position of the piston 402 exists, the CPU 501 proceeds to S908. In S908, the CPU 501 (display control unit 516) turns on the LED 305 corresponding to the position of the piston 402. Thereafter, the CPU 501 proceeds from S908 to S909. On the other hand, there may be no LED 305 corresponding to the position of the piston 402. For example, as illustrated in FIG. 7C, when the piston 402 further moves after the position of the piston 402 is specified, the position of the piston 402 may become unspecifiable. In this case, the CPU 501 proceeds from S907 to S920. In S920, the CPU 501 (display control unit 516) turns on the LED 305 disposed on the outermost side among the plurality of LEDs 305. For example, the leftmost or rightmost LED 305 that was turned on last may be decided as the LED 305 corresponding to the position of the piston 402. Moreover, the CPU 501 selects a color indicating that the position detection has failed or a color indicating that the piston 402 exists outside the detectable range as the lighting color of the leftmost or rightmost LED 305 that has been turned on last. Thereafter, the CPU 501 proceeds from S920 to S912.

In S909, the CPU 501 (position specification unit 512 or display control unit 516) determines whether the position of the piston 402 is within the detection range. Here, the first detection range 801, the second detection range 802, and the like included in the setting information are compared with the position of the piston 402. In a case where the position of the piston 402 is not included in any detection range, the CPU 501 proceeds from S909 to S912. In a case where the position of the piston 402 is included in any of the detection ranges, the CPU 501 proceeds from S909 to S910.

In S910, the CPU 501 (display control unit 516) turns on the output LED corresponding to the detection range including the position of the piston 402 among the plurality of detection ranges. In a case where the piston 402 exists in the first detection range 801, the first output LED 205 is turned on. In a case where the piston 402 exists in the second detection range 802, the second output LED 206 is turned on. In a case where the piston 402 exists in the j-th detection range, the LEDs corresponding to the j-th detection range and the j-th output signal are turned on.

In step S911, the CPU 501 (output unit 517) outputs, to the relay amplifier 104, an output signal corresponding to a detection range including the position of the piston 402 among the plurality of output signals (control outputs). In a case where the piston 402 exists in the first detection range 801, the first output signal is output. In a case where the piston 402 exists in the second detection range 802, the second output signal is output. In a case where the piston 402 exists in the j-th detection range, the j-th output signal is output.

In S912, the CPU 501 determines whether the power supply is turned off (the supply of power from the relay amplifier 104 is stopped). When the power supply is not turned off, the CPU 501 returns from S912 to S903. When the power supply is turned off, the display control method ends.

### 7. Flowchart of Setting Method

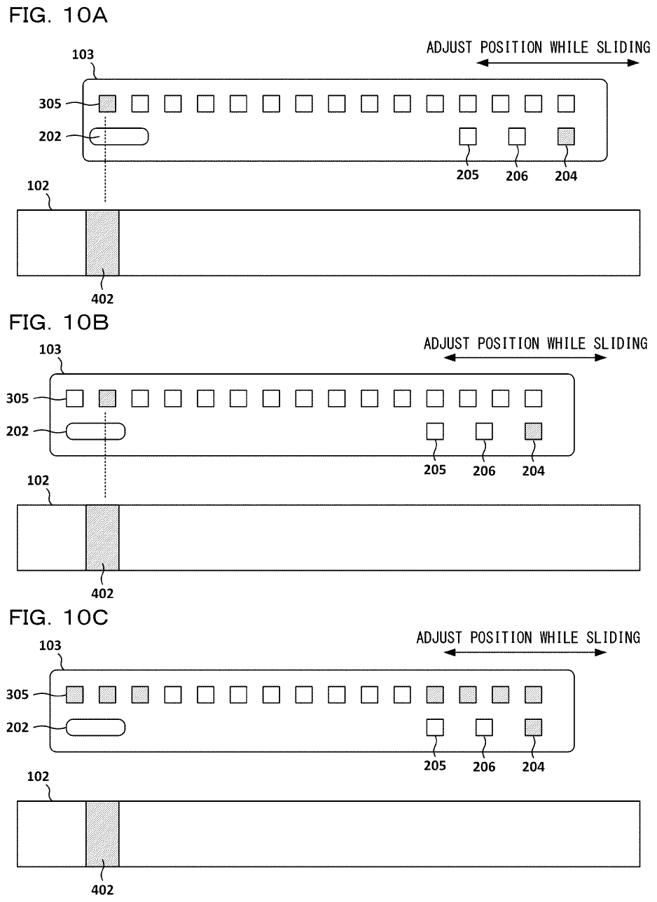

FIG. 10A illustrates work for attaching the cylinder sensor 103 to the air cylinder 102 and installing the cylinder sensor 103 at a desired position. The user pushes and pulls the piston rod 401 to install the piston 402 at a desired position in the air cylinder 102. The user inserts the cylinder sensor 103 into the groove 131 of the air cylinder 102 and slides the cylinder sensor 103 in the groove 131 to position the cylinder sensor 103. According to this example, among the plurality of LEDs 305, the leftmost LED 305 corresponding to the position of the piston 402 is turned on. Note that the execution order of the temporary installation of the cylinder sensor 103 in the air cylinder 102 and the positioning of the piston rod 401 may be reversed. In any case, a fine adjustment of the position of the cylinder sensor 103 would be executed as follows.

FIG. 10B illustrates that the cylinder sensor 103 is further moved to the left. Note that the air cylinder 102 moves relatively to the right with respect to the cylinder sensor 103. The CPU 501 detects the position of the piston 402 and turns on the second LED 305 from the left corresponding to the position of the piston 402. When the piston 402 is positioned at a desired position, the user long-presses the operation button 202. The long press period is, for example, 2 seconds. The CPU 501 may measure the time during which the operation button 202 is pressed and specify the user's instruction according to the measured time. The memory 502 may store a table indicating a relationship between the time and the instruction. The CPU 501 specifies the user instruction by referring to the table on the basis of the measured time.

When detecting a long press of the operation button 202 through the operation switch 303, the CPU 501 (setting unit 513) transitions from an operation mode to a setting mode.

As illustrated in FIG. 10C, in the setting mode, the CPU 501 turns on some LEDs 305 to display a symbol indicating that the setting mode is being performed. This symbol may be, for example, blinking four LEDs at the right end among the plurality of LEDs 305. The LED 305 that is turned on among the four LEDs 305 may be switched in order from right to left.

The CPU 501 turns on the Mi LEDs 305 corresponding to the i-th detection range on the basis of the position of the piston 402 detected using the Hall element 304 and the width of the detection range. In this example, the width Mi of the i-th detection range is set to 3. Therefore, one LED 305 corresponding to the position of the piston 402, the LED 305 on the right side thereof, and the LED 305 on the left side thereof are turned on. As a result, the user can visually recognize the detection range. The user may further slide the cylinder sensor 103 while checking that the Mi LEDs 305 corresponding to the i-th detection range are turned on. As a result, in a case where the position of the i-th detection range is confirmed, the user long-presses the operation button 202. The long press period is, for example, 2 seconds.

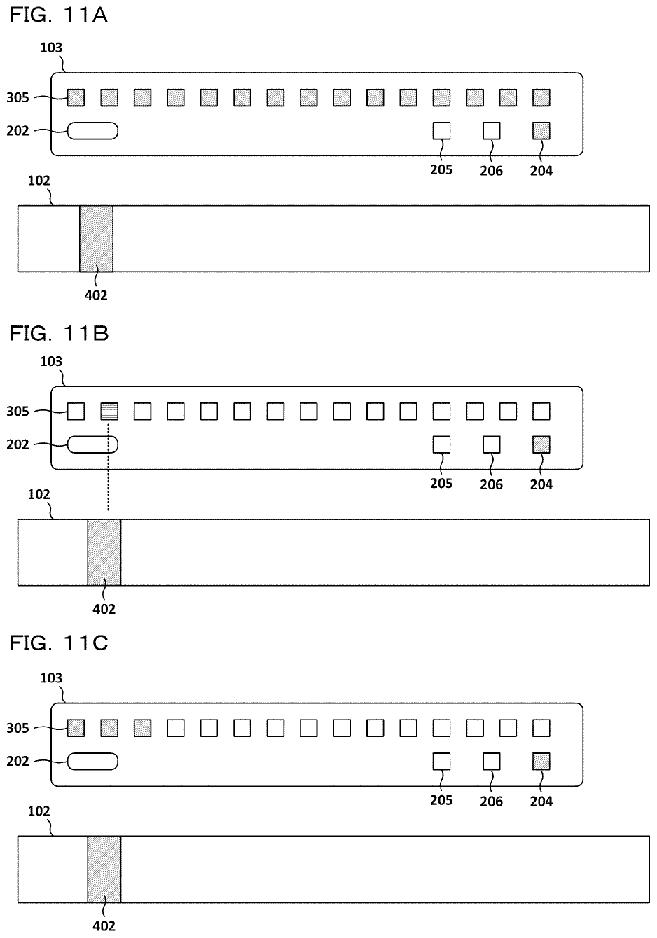

FIG. 11A illustrates a symbol indicating that the detection range is confirmed. According to this example, the CPU 501 simultaneously turns on all of the LEDs 305 among the plurality of LEDs 305 to display a confirmation symbol.

FIG. 11B illustrates a symbol indicating that the setting of the detection range is completed. According to this example, the CPU 501 displays a setting completion symbol by blinking the LED 305 located at the center of the set detection range among the plurality of LEDs 305 for a predetermined time. Note that the symbol illustrated in FIG. 11B may be displayed following the symbol illustrated in FIG. 11A, or only one of the symbols may be displayed. Alternatively, the confirmation symbol illustrated in FIG. 11A may be displayed while the operation button 202 is pressed even after a predetermined time elapses. Thereafter, when the finger is released from the operation button 202, the setting completion symbol in FIG. 11B may be displayed.

FIG. 11C illustrates a state after the setting completion symbol illustrated in FIG. 11B is displayed for a predetermined time. Here, a symbol indicating a set detection range is displayed. That is, the CPU 501 transitions from the setting mode to the operation mode.

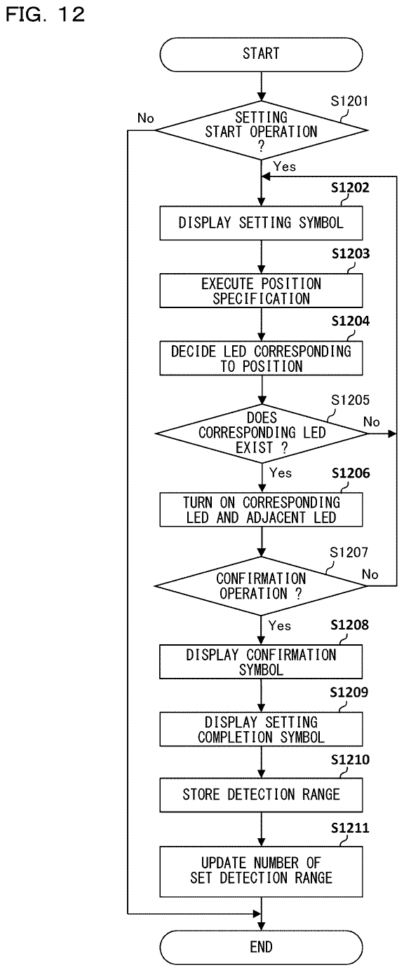

FIG. 12 is a flowchart illustrating a setting method of a detection range executed by the CPU 501 in accordance with the control program 521. The memory 502 may store a variable h indicating the number of set detection ranges. In a case where there is no set detection range, zero is substituted for the variable h. In a case where one detection range has been set, 1 is substituted for the variable h.

In S1201, the CPU 501 (setting unit 513) determines whether a setting start operation has been input. The setting start operation may be, for example, that the operation button 202 is continuously pressed down for a predetermined time (example: 2 seconds) in the operation mode. The setting start operation may be that the operation button 202 is double-clicked.

In S1202, the CPU 501 (display control unit 516) displays a setting symbol using the plurality of LEDs 305. For example, the setting symbol as illustrated in FIG. 10C may be displayed.

In S1203, the CPU 501 (position specification unit 512) executes position calculation for specifying the position of the piston 402 on the basis of the detection result of the Hall element 304.

In S1204, the CPU 501 (position specification unit 512 or display control unit 516) decides the LED 305 corresponding to the position of the piston 402.

In S1205, the CPU 501 (position specification unit 512 or display control unit 516) determines whether the LED 305 corresponding to the position of the piston 402 exists. The cylinder sensor 103 may not yet be installed in the air cylinder 102, or the piston 402 may deviate from the detectable range. In this case, it is determined that the corresponding LED 305 does not exist, and the CPU 501 returns from S1205 to S1202. In a case where the corresponding LED 305 exists, the CPU 501 proceeds from S1205 to S1206.

In S1206, the CPU 501 (display control unit 516) turns on the corresponding LED 305 and the adjacent LED 305. As described above, the Mi LEDs 305 corresponding to the width of the detection range are turned on.

In step S1207, the CPU 501 (range setting unit 514) determines whether a confirmation operation of the detection range is input to the operation button 202. In a case where the confirmation operation is not input, the CPU 501 returns from S1207 to S1202. In a case where the confirmation operation is input, the CPU 501 proceeds from S1207 to S1208.

In S1208, the CPU 501 (display control unit 516) displays a confirmation symbol using the plurality of LEDs 305. For example, the confirmation symbol may be the symbol illustrated in FIG. 11A.

In S1209, the CPU 501 (display control unit 516) displays the setting completion symbol using the plurality of LEDs 305. For example, the setting completion symbol may be the symbol illustrated in FIG. 11B.

In S1210, the CPU 501 (range setting unit 514) stores setting information indicating the i-th detection range in the memory 502. Here, i is obtained by adding 1 to the variable h. The setting information may include position information indicating a position of the i-th detection range and width information indicating a width (an initial value or a value set by the user). Here, the position information indicates at least one of the left end, the center, and the right end of the detection range. The range setting unit 514 may assign, to the i-th detection range, a lighting color that is not assigned to any of the (i−1) th detection range from the first detection range, and store color information indicating the lighting color in the setting information.

In S1211, the CPU 501 (range setting unit 514) updates the variable h indicating the number of set detection ranges. That is, 1 is added to the value of the variable h. Alternatively, the variable i is substituted into the variable h.

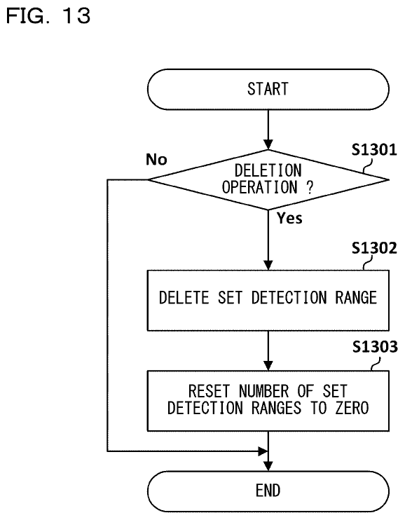

FIG. 13 is a flowchart illustrating a method of deleting set detection ranges in bulk.

In step S1301, the CPU 501 (setting unit 513) determines whether a bulk deletion operation has been input for the operation button 202. For example, in the operation mode, when the operation button 202 is pressed continuously for a predetermined time (example: 3 seconds) or when 3 short presses are input to the operation button 202, the CPU 501 may determine that the bulk deletion is instructed. An upper limit value may be determined for the number of detection ranges. In this case, the bulk deletion operation may be that the number of set detection ranges matches the upper limit value and a long press of the operation button 202 is detected. When the bulk deletion is instructed, the CPU 501 proceeds from S1301 to S1302.

In S1302, the CPU 501 (range setting unit 514) deletes the set detection range. For example, the CPU 501 deletes the information of all the set detection ranges from the setting information stored in the memory 502.

In S1303, the CPU 501 (range setting unit 514) resets the set number h of detection ranges to 0.

### 8. Setting of Width of Detection Range

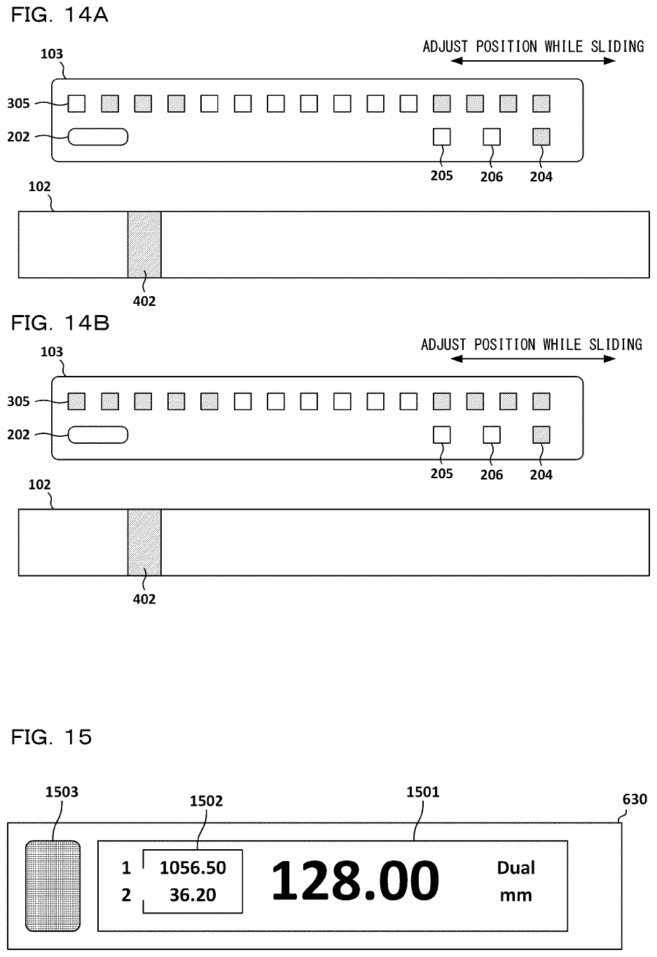

FIGS. 14A and 14B illustrate work of setting the width of the detection range in the setting mode. The setting of the width of the detection range may be included in, for example, S1206.

FIG. 14A illustrates that the width Mi is set to 3. FIG. 14B illustrates that the width Mi is set to 5. For example, in a case where there is a plurality of selectable widths, each time the operation button 202 is short-pressed, the CPU 501 (width setting unit 515 and display control unit 516) switches the width and turns on and off the adjacent LED corresponding to the width. For example, when the operation button 202 is short-pressed in a case where the width Mi is 3 as illustrated in FIG. 14A, the width Mi is changed to 5 as illustrated in FIG. 14B. When the operation button 202 is short-pressed in a case where the width Mi is 5 as illustrated in FIG. 14B, the width Mi is changed to 3 as illustrated in FIG. 14A. In this manner, a plurality of width values may be switched while being circulated. The selectable width may be three or more kinds. Also in this case, the width value is switched while being circulated.

### 9. Display of Distance in Relay Amplifier

FIG. 15 illustrates a screen displayed on the OLED display 630 of the relay amplifier 104. The relay amplifier 104 can receive information indicating a detection range (threshold) and information indicating a detection position of the piston 402 from the cylinder sensor 103. Moreover, the relay amplifier 104 can receive the first output signal, the second output signal, and the i-th output signal.

As illustrated in FIG. 15, the distance display region 1501 is a region in which the position of the piston 402 is displayed as a distance from a reference position. The distance display region 1501 may display a unit of distance (example: mm).

The threshold display region 1502 indicates a threshold of each detection range (output signal). In this example, it is illustrated that the threshold of the first output signal corresponding to the first detection range 801 is 1056.50 mm. Here, the threshold may be any one of the right end, the center, and the left end of the first detection range 801. It is also illustrated that the threshold of the second output signal corresponding to the second detection range 802 is 36.20 mm.

The output identification region 1503 is a region that displays which of the first output signal and the second output signal is output. That is, the output identification region 1503 may indicate in which detection range the position of the piston 402 exists. For example, in a case where the piston 402 exists in the first detection range 801, the output identification region 1503 may be turned on in blue. In a case where the piston 402 exists in the second detection range 802, the output identification region 1503 may be turned on in orange. In a case where the piston 402 exists in the intermediate range between the first detection range 801 and the second detection range 802, the output identification region 1503 may display other colors (examples: black, white, green).

### 10. Examples of Other Symbols

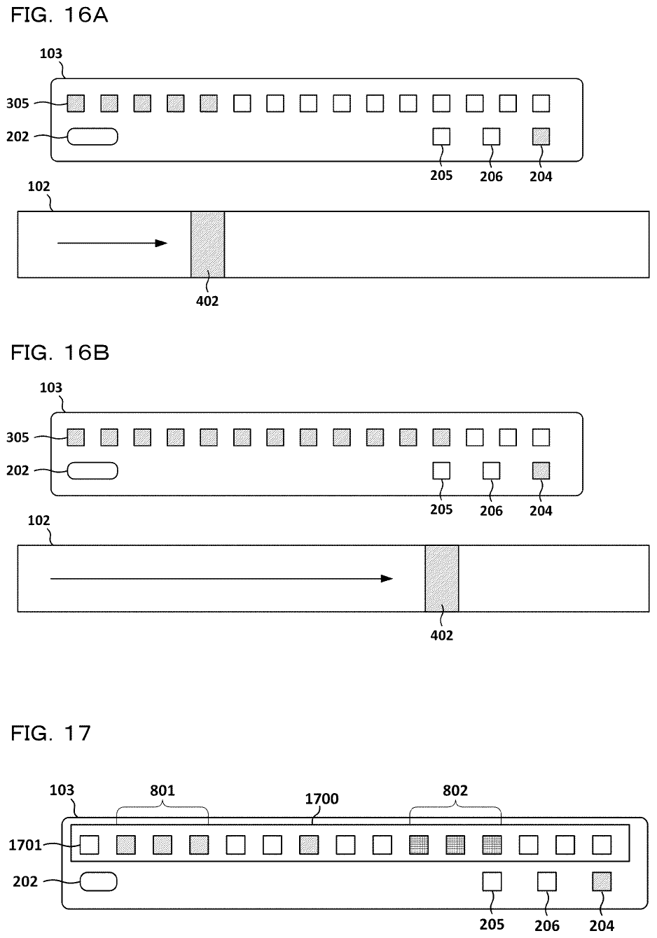

FIGS. 16A and 16B illustrate another example of the symbol indicating the position of the piston 402. Here, it is assumed that the reference position is set on the left end side of the cylinder sensor 103. When detecting the position of the piston 402, the CPU 501 turns on all the LEDs 305 existing from the left end to the detection position among the plurality of LEDs 305. The user can recognize the moving distance of the piston 402 from the reference position from the number of the LEDs 305 that are turned on. As a bar whose length changes according to the moving distance in this manner, a symbol suggesting the position of the piston 402 may be realized.

According to the above-described embodiment, the plurality of LEDs 305 is arranged immediately below the display window 203, but this is merely an example. For example, a light guide (examples: optical fiber, resin having translucency) may be disposed between the plurality of LEDs 305 disposed on the control board 302 and the display window 203. This will increase the degree of freedom of installation of the plurality of LEDs 305.

FIG. 17 illustrates another example of a symbol indicating the position of the piston 402. The OLED display 630 shows a position symbol 1701 imitating the LEDs 305 indicating the position of the piston 402, the first detection range 801, and the second detection range 802. As described above, the OLED display 630 may be adopted instead of the plurality of LEDs 305. The OLED display 630 may be a liquid crystal display.

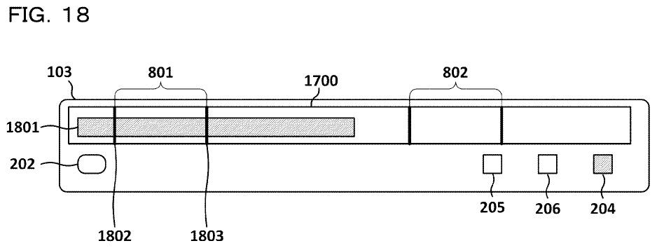

FIG. 18 illustrates another example of symbols indicating the position of the piston 402, the first detection range 801, and the second detection range 802. A bar symbol 1801 is an image indicating the position of the piston 402. The CPU 501 lengthens or shortens the bar symbol 1801 according to the position of the piston 402. The range symbols 1802 and 1803 are images indicating the boundaries of the detection range. The CPU 501 may display the range symbols 1802 and 1803 indicating the detection ranges on the basis of the position information and the width information of the detection ranges included in the setting information stored in the memory 502.

Note that the OLED display 630 may also display the first output LED 205 and the second output LED 206 as images.

### 11. Details of Display Control Method in Relay Amplifier

In the above-described embodiment, the display control method in the cylinder sensor 103 has been mainly described. Furthermore, as suggested in the above-described embodiment, the relay amplifier 104 and the display panel 105 may display the symbol instead of or in conjunction with the display of the symbol in the cylinder sensor 103. Displaying a symbol related to the position of the displacement body by the relay amplifier 104 and the display panel 105 may be particularly useful in a case where the cylinder sensor 103 does not have a display function or in a case where display capability of the display function is small. A user interface (UI) in the relay amplifier 104 will be described below, but this is also a UI that can be employed in the display panel 105.

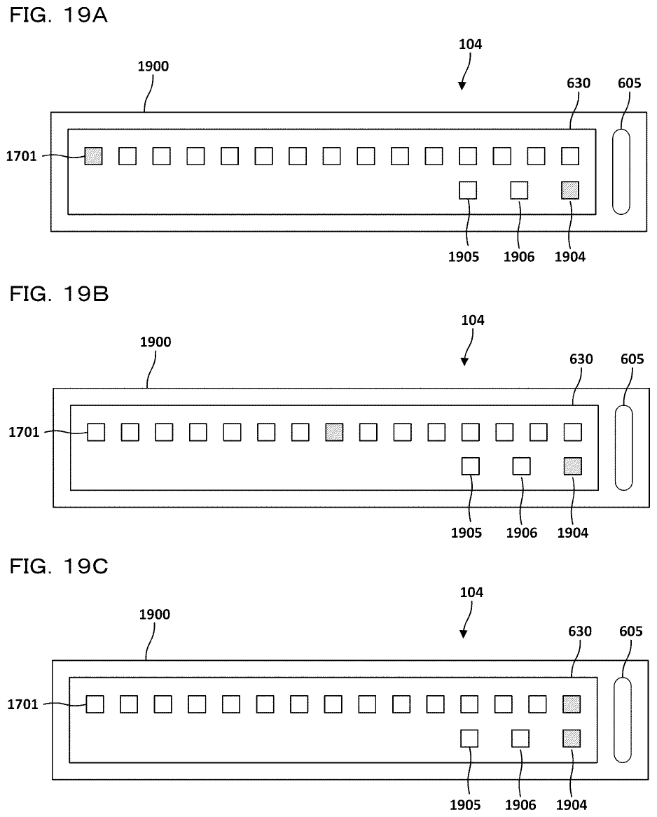

FIGS. 19A to 19C illustrate examples of display screens on the OLED display 630 provided in the housing 1900 of the relay amplifier 104. The OLED display 630 is merely an example, and a liquid crystal display (LCD) may be adopted. In this example, the OLED display 630 displays a plurality of position icons (position symbols 1701) imitating the LEDs 305, a power supply symbol 1904 imitating the power supply LEDs 204, a first output symbol 1905 imitating the first output LEDs 205, and a second output symbol 1906 imitating the second output LEDs 206.

When receiving the position information indicating the position of the piston 402 detected by the cylinder sensor 103 from the cylinder sensor 103, the display control unit 616 of the relay amplifier 104 changes the position symbol 1701 corresponding to the position information among a plurality of the position symbols 1701 from the default color (examples: white, black) to the first color (example: green). In FIG. 19A, since the piston 402 exists at the left end of a displaceable range, the color of the position symbol 1701 disposed at the left end among the plurality of position symbols becomes green. According to FIG. 19B, since the piston 402 exists at the intermediate position, the color of the position symbol disposed at the intermediate position among the plurality of position symbols becomes green. According to FIG. 19C, since the piston 402 exists at the right end of the displaceable range, the color of the position symbol 1701 disposed at the right end among the plurality of position symbols 1701 becomes green. In this manner, the position symbol 1701 disposed at different positions according to the position of the piston 402 may be displayed in a color different from the other position symbols 1701.

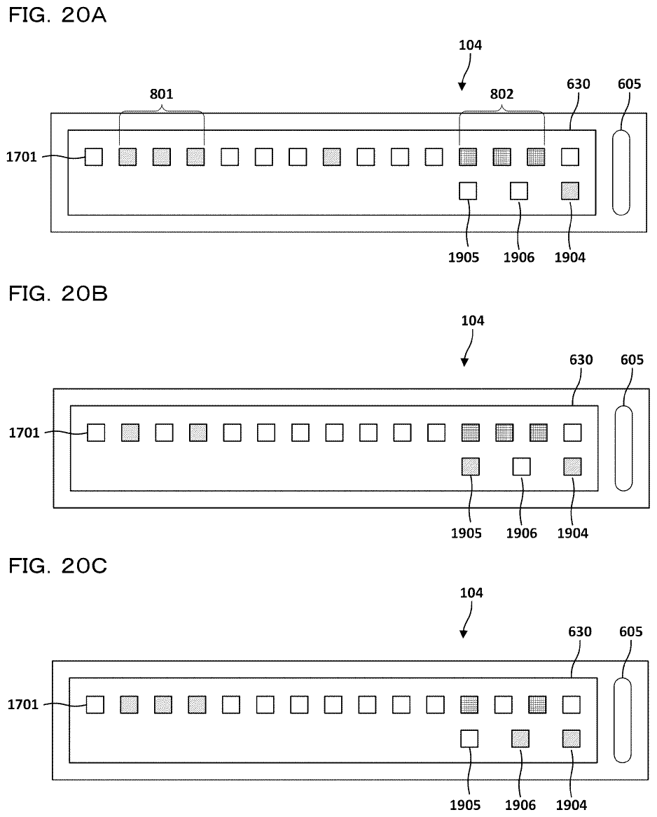

FIGS. 20A to 20C illustrate the position symbol 1701 and the threshold symbol when the first detection range 801 and the second detection range 802 are set by the cylinder sensor 103 or the relay amplifier 104. Here, the threshold symbol is a concept that can include the position symbol 1701 indicating the first detection range 801 and the second detection range 802 among the plurality of position symbols 1701, the position symbol 1701 or the first output symbol 1905 indicating that the piston 402 exists in the first detection range 801, the position symbol 1701 or the second output symbol 1906 indicating that the piston 402 exists in the second detection range 802, and the like. As described above, the detection range may be defined by a position (threshold) and a width. Therefore, these symbols may be referred to as threshold symbols.

According to FIG. 20A, the display control unit 616 displays the position symbol 1701 corresponding to the first detection range 801 in the third color (example: blue) and displays the position symbol 1701 corresponding to the second detection range 802 in the fourth color (example: orange) on the basis of the setting information received from the cylinder sensor 103 or the setting information stored in the memory 602. Here, the lighting colors of the plurality of LEDs 305 corresponding to the detection range in the cylinder sensor 103 and the display color of the position symbol indicating the detection range displayed on the relay amplifier 104 may coincide with each other or may be different from each other. According to FIG. 20A, since the position of the piston 402 is the intermediate position, the position symbol corresponding to the intermediate position is displayed in the first color. Since the position of the piston 402 is not included in the first detection range 801, the display control unit 616 displays the first output symbol 1905 in the default color. Since the position of the piston 402 is not included in the second detection range 802, the display control unit 616 displays the second output symbol 1906 in the default color.

FIG. 20B illustrates that the piston 402 has moved to a position included in the first detection range 801. On the basis of the position information received from the cylinder sensor 103, the display control unit 616 changes the color of the position symbol 1701 corresponding to the position of the piston 402 among the plurality of position symbols 1701 corresponding to the first detection range 801 to a color different from the color of the adjacent position symbol 1701. As a result, the position of the first detection range 801 and the position of the piston 402 are displayed in a distinguishable manner. The display control unit 616 switches the color of the first output symbol 1905 from the default color to the third color (example: blue) on the basis of the first output signal output from the cylinder sensor 103. As a result, the user can recognize that the piston 402 is located in the first detection range 801 and that the first output signal is output from the cylinder sensor 103.

FIG. 20C illustrates that the piston 402 has moved to a position included in the second detection range 802. On the basis of the position information received from the cylinder sensor 103, the display control unit 616 changes the color of the position symbol corresponding to the position of the piston 402 among the plurality of position symbols corresponding to the second detection range 802 to a color different from the color of the adjacent position symbol. As a result, the position of the second detection range 802 and the position of the piston 402 are displayed in a distinguishable manner. The display control unit 616 switches the color of the second output symbol 1906 from the default color to the fourth color (example: orange) on the basis of the second output signal output from the cylinder sensor 103. As a result, the user can recognize that the piston 402 is located in the second detection range 802 and that the second output signal is output from the cylinder sensor 103.

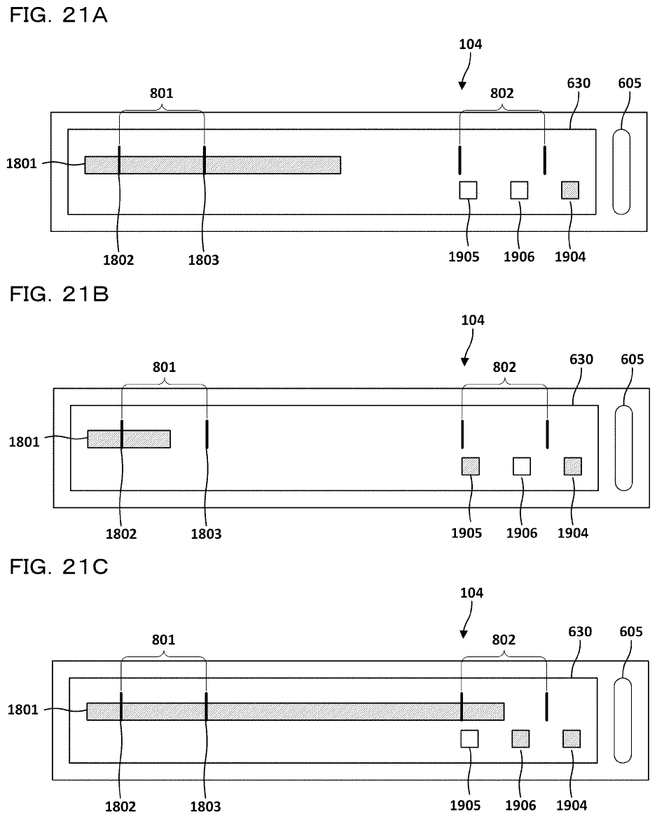

FIGS. 21A to 21C illustrate that the position symbol is realized by the bar symbol 1801. It has already been described with reference to FIG. 18 that the cylinder sensor 103 can display the position symbol (bar symbol 1801) and the threshold symbol (range symbols 1802 and 1803). Similarly, the relay amplifier 104 may display the bar symbol 1801 and the threshold symbol (range symbols 1802 and 1803).

FIG. 21A illustrates the bar symbol 1801 in a case where the position of the piston 402 is the intermediate position. The bar symbol 1801 is a variable length bar image. The range symbols 1802 and 1803 are threshold symbols indicating the detection range. In this example, the range symbols 1802 and 1803 are illustrated by vertical lines, but may be images other than the vertical lines. The range symbols 1802 and 1803 may be, for example, images such as arrows or triangles, which suggests a width and a threshold of the detection range.

FIG. 21B illustrates the bar symbol 1801 in a case where the position of the piston 402 is included in the first detection range 801. In this example, since the reference position of the bar symbol 1801 is set on the left end side, the length of the bar symbol 1801 is shortened. Furthermore, since the first output signal is output, the first output symbol 1905 is displayed in the second color.

FIG. 21C illustrates the bar symbol 1801 in a case where the position of the piston 402 is included in the second detection range 802. In this example, the length of the bar symbol 1801 is increased. Since the second output signal is output, the second output symbol 1906 is displayed in the third color.

Since the relay amplifier 104 also includes the operation switch 605, the detection range (threshold, width) can be set by operating the operation switch 605. That is, the operation switch 605 is used instead of the operation button 202.

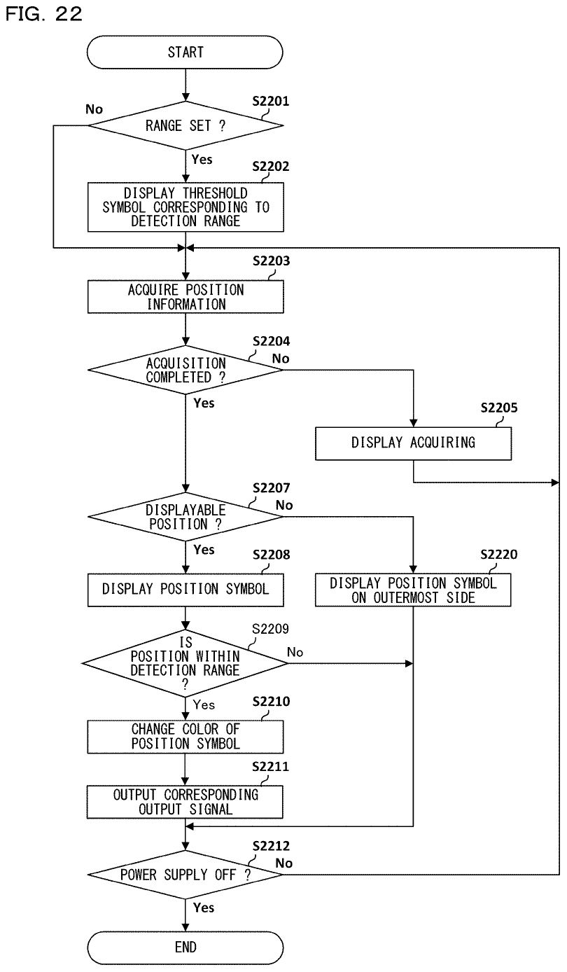

FIG. 22 illustrates a display control method executed by the CPU 601 of the relay amplifier 104 in accordance with the control program 621. When the CPU 601 is activated by power supplied from the valve system 101, the following processing is executed.

In S2201, the CPU 601 (display control unit 616) refers to the setting information stored in the memory 602, and determines whether one or more detection ranges are set. The CPU 601 acquires the setting information from the cylinder sensor 103 and stores the setting information in the memory 602 in advance. When one or more detection ranges are not set, the CPU 601 skips S2202 and proceeds to S2203. When one or more detection ranges are set, the CPU 601 proceeds to S2202.

In S2202, the CPU 601 (display control unit 616) displays a threshold symbol at a position corresponding to the detection range. The threshold symbol may be realized by a plurality of position symbols 1701, may be realized by a bar symbol 1801, or may be realized by range symbols 1802 and 1803. The setting information may include color information indicating the display color of the threshold symbol corresponding to the i-th detection range. The CPU 601 causes the OLED display 630 to display the threshold symbol corresponding to the i-th detection range in the color corresponding to the color information in accordance with the color information. The setting information may include a variable Mi indicating the width of the i-th detection range. The CPU 601 adjusts the width of the threshold symbol according to the variable Mi.

In S2203, the CPU 601 (position specification unit 618) acquires position information from the cylinder sensor 103. Here, the position information may be a numerical value indicating the position of the piston 402, or may be raw data of detection results of the plurality of Hall elements 304. In the latter case, the position specification unit 618 specifies the position of the piston 402 by executing the same position calculation as the position specification unit 512.

In S2204, the CPU 601 (position specification unit 618 or display control unit 616) determines whether the acquisition of the position information has been completed. For example, in a case where the cylinder sensor 103 is not attached to the air cylinder 102, the position calculation fails, and the acquisition of the position information also fails. On the other hand, in a case where the cylinder sensor 103 is correctly attached to the air cylinder 102, the position calculation is successful, and thus the position information is also successfully acquired. In a case where the position information has not been acquired, the CPU 601 proceeds to S2205. In S2205, the CPU 601 (display control unit 616) displays a symbol indicating that the position information is being acquired using the plurality of position symbols 1701. Thereafter, the CPU 601 returns from S2205 to S2203, and continues the acquisition of the position information. On the other hand, in a case where the position information of the piston 402 has been acquired, the CPU 601 proceeds to S2207.

In S2207, the CPU 601 (the position specification unit 618 or the display control unit 616) determines whether the position symbol 1701 can be displayed at the display position corresponding to the position of the piston 402. In a case where the position symbol 1701 can be displayed on the screen of the OLED display 630, the CPU 601 proceeds to S2208. In step S2208, the CPU 601 (display control unit 616) displays the position symbol 1701 at the display position corresponding to the position of the piston 402. Thereafter, the CPU 601 proceeds from S2208 to S2209. On the other hand, in a case where the position symbol 1701 cannot be displayed at the display position corresponding to the position of the piston 402, the CPU 601 proceeds from S2207 to S2220. In S2220, the CPU 601 (display control unit 616) displays the position symbol 1701 on the outermost side on the OLED display 630. Moreover, the CPU 601 selects a color indicating that the detection of the position has failed or a color indicating that the piston 402 is outside the detectable range as the lighting color of the position symbol 1701. The CPU 601 may blink the position symbol 1701. Thereafter, the CPU 601 proceeds from S2220 to S2212.

In S2209, the CPU 601 (position specification unit 618 or display control unit 616) determines whether the position of the piston 402 is within the detection range. Here, the first detection range 801, the second detection range 802, and the like included in the setting information are compared with the position of the piston 402. In a case where the position of the piston 402 is not included in any detection range, the CPU 601 proceeds from S2209 to S2212. In a case where the position of the piston 402 is included in any of the detection ranges, the CPU 601 proceeds from S2209 to S2210.

In S2210, the CPU 601 (display control unit 616) turns on the output symbol corresponding to the detection range including the position of the piston 402 among the plurality of detection ranges. In a case where the piston 402 exists in the first detection range 801, the first output symbol 1905 is turned on. In a case where the piston 402 exists in the second detection range 802, the second output symbol 1906 is turned on. In a case where the piston 402 exists in the j-th detection range, the output symbols corresponding to the j-th detection range and the j-th output signal are turned on.

In S2211, the CPU 601 (output unit 617) outputs an output signal corresponding to a detection range including the position of the piston 402 among the plurality of output signals (control outputs) to the valve system 101. In a case where the piston 402 exists in the first detection range 801, the first output signal is output. In a case where the piston 402 exists in the second detection range 802, the second output signal is output. In a case where the piston 402 exists in the j-th detection range, the j-th output signal is output.

In S2212, the CPU 601 determines whether the power supply is turned off (the supply of power from the relay amplifier 104 is stopped). When the power supply is not turned off, the CPU 601 returns from S2212 to S2203. When the power supply is turned off, the display control method ends.

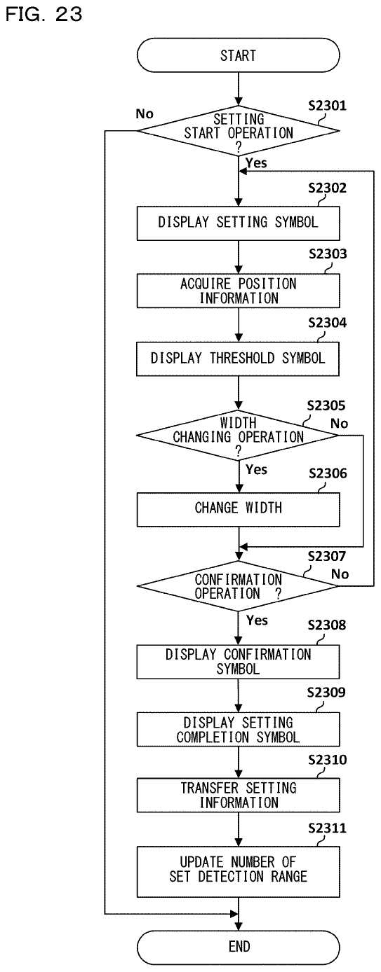

FIG. 23 is a flowchart illustrating a setting method of a detection range executed by the CPU 601 in accordance with the control program 621. The memory 602 may store a variable h indicating the number of set detection ranges. In a case where there is no set detection range, zero is substituted for the variable h. In a case where one detection range has been set, 1 is substituted for the variable h.

In S2301, the CPU 601 (setting unit 613) determines whether a setting start operation has been input. The setting start operation may be, for example, that the operation switch 605 is continuously pushed down for a predetermined time (example: 2 seconds) in the operation mode. The setting start operation may be that the operation switch 605 is double-clicked.

In S2302, the CPU 601 (display control unit 616) displays the setting symbol. For example, the setting symbol as illustrated in FIG. 10C may be displayed. The setting symbol includes at least one of an image and a character that means that the setting is in progress.

In S2303, the CPU 601 (position specification unit 618) acquires position information indicating the position of the piston 402 from the cylinder sensor 103.

In S2304, the CPU 601 (position specification unit 618 or display control unit 616) displays a threshold symbol on the basis of the position information. The threshold symbol is disposed at a display position of the OLED display 630 corresponding to the current position of the piston 402. The width of the threshold symbol is an initial value.

In S2305, the CPU 601 (position specification unit 618 or display control unit 616) determines whether a width changing operation is input to the operation switch 605. The width changing operation may be, for example, a short press of the operation switch 605. In a case where the width changing operation is not input, the CPU 601 proceeds from S2305 to S2307. In a case where the width changing operation is input, the CPU 601 proceeds from S2305 to S2306.

In S2306, the CPU 601 (display control unit 616) changes the width of the threshold symbol (detection range) by about one step. As described above, the width may be cyclically changed every time the width changing operation is input. For example, the width may circulate like 2⇒4⇒6⇒2⇒4.

In step S2307, the CPU 601 (range setting unit 634) determines whether a confirmation operation of the detection range is input to the operation switch 605. In a case where the confirmation operation is not input, the CPU 601 returns from S2307 to S2302. In a case where the confirmation operation is input, the CPU 601 proceeds from S2307 to S2308.

In S2308, the CPU 601 (display control unit 616) displays a confirmation symbol using the plurality of position symbols 1701. For example, the confirmation symbol may be the symbol illustrated in FIG. 11A. The confirmation symbol may be an image or a character indicating confirmation.

In S2309, the CPU 601 (display control unit 616) displays the setting completion symbol using a plurality of position symbols. For example, the setting completion symbol may be the symbol illustrated in FIG. 11B. The setting completion symbol may be an image or a character indicating completion.

In S2310, the CPU 601 (range setting unit 634) stores setting information indicating the i-th detection range in the memory 602, and transfers the setting information to the cylinder sensor 103. The CPU 501 of the cylinder sensor 103 receives the setting information and stores the setting information in the memory 502. Here, i is obtained by adding 1 to the variable h. The setting information may include position information indicating a position of the i-th detection range and width information indicating a width (an initial value or a value set by the user). Here, the position information indicates at least one of the left end, the center, and the right end of the detection range. The range setting unit 634 may assign, to the i-th detection range, a lighting color that is not assigned to any of the (i−1) th detection range from the first detection range, and store color information indicating the lighting color in the setting information.

In S2311, the CPU 601 (range setting unit 634) updates the variable h indicating the number of set detection ranges. That is, 1 is added to the value of the variable h. Alternatively, the variable i is substituted into the variable h.

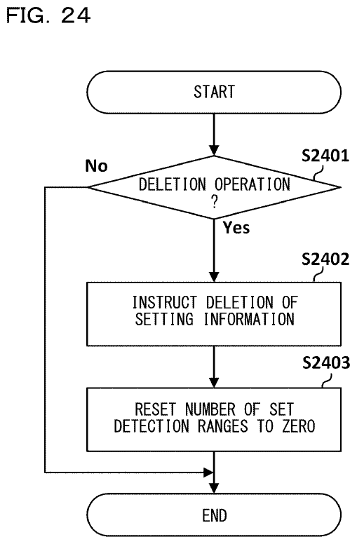

FIG. 24 is a flowchart illustrating a method of deleting set detection ranges in bulk.

In step S2401, the CPU 601 (setting unit 613) determines whether a bulk deletion operation has been input to the operation switch 605. For example, when the operation switch 605 is pressed continuously for a predetermined time (example: 3 seconds) or when 3 short presses are input to the operation switch 605 in the operation mode, the CPU 601 may determine that the bulk deletion is instructed. An upper limit value may be determined for the number of detection ranges. In this case, the bulk deletion operation may be that the number of set detection ranges matches the upper limit value and a long press of the operation switch 605 is detected. When the bulk deletion is instructed, the CPU 601 proceeds from S2401 to S2402.

In S2402, the CPU 601 (range setting unit 634) deletes the set detection range from the memory 602 and transmits a deletion instruction to the cylinder sensor 103. When receiving the deletion instruction, the CPU 501 of the cylinder sensor 103 deletes information of all set detection ranges from the setting information stored in the memory 502.

In S2403, the CPU 601 (range setting unit 634) resets the number h of the set detection ranges to 0.

### 12. Display Control Method in Display Panel

### 12-1. Structure of Display Panel

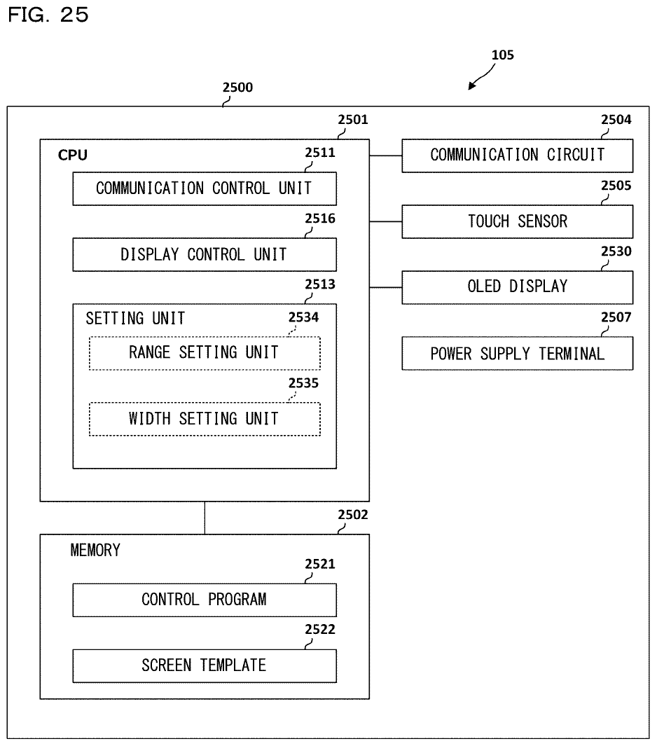

FIG. 25 illustrates a structure of the display panel 105. The display panel 105 includes a housing 2500. The housing 2500 accommodates and protects various components.

A CPU 2501 realizes various functions by executing a control program 2521 stored in a memory 2502. The memory 2502 includes a ROM, a RAM, and the like. A communication circuit 2504 is a circuit that is connected to the valve system 101 via an Ethernet cable and transmits and receives signals in accordance with a predetermined communication protocol. A power supply terminal 2507 is a terminal that receives power supplied from the valve system 101. In a case where power over Ethernet (PoE) is employed, the power supply terminals 2507 serve as some terminals of an RJ45 connector. The registered jack (RJ)45 is a standard registered with the United States Federal Communications Commission.

When the display panel 105 is powered on and activated, a communication control unit 2511 assigns a predetermined IP address to itself, and attempts connection to the valve system 101 to which another predetermined IP address has been assigned in advance. IP is an abbreviation of Internet protocol. When the connection is successful, the communication control unit 2511 can acquire various information of the cylinder sensor 103 via the valve system 101 and the relay amplifier 104. This information includes position information indicating the position of the piston 402, setting information indicating the position and width of the detection range, information indicating the correspondence relationship between the detection range and the output signal, model information and identification information of the cylinder sensor 103, and the like.

A touch sensor 2505 detects a touch of a human finger or a touch of a touch pen. An OLED display 2530 displays information acquired from the valve system 101, the relay amplifier 104, and the cylinder sensor 103, and displays a setting screen for setting these. A display control unit 2516 displays the setting screen and the operation screen on the OLED display 2530 using a screen template 2522 stored in the memory 2502. The operation screen is, for example, a screen that displays the position symbol 1701 indicating the position of the piston 402 detected by the cylinder sensor 103, a threshold symbol indicating the detection range, and the like.

A setting unit 2513 is an option, and executes setting processing similar to the setting units 513 and 613. A range setting unit 2534 sets a position (example: a threshold) of a detection range of the cylinder sensor 103. A width setting unit 2535 sets a width of the detection range.

### 12-2. Operation Screen

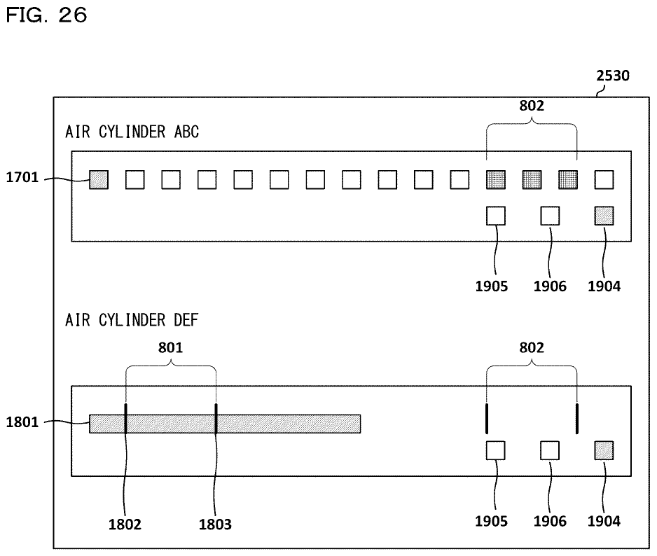

FIG. 26 illustrates an operation screen displayed on the display panel 105. The valve system 101 generally controls the plurality of air cylinders 102. Therefore, the display panel 105 may display the operation states of the plurality of air cylinders 102.

In the upper display region of FIG. 26, the operation state of the first air cylinder 102 is illustrated. The display control unit 2516 displays an operation state corresponding to the output signal from the air cylinder 102 on the OLED display 2530 with respect to the screen template 2522. The name of the first air cylinder 102 is “air cylinder ABC”. This name may be acquired from the cylinder sensor 103. The current position of the piston 402 of the first air cylinder 102 is the left end in the displaceable range. Therefore, the position symbol 1701 at the left end among the plurality of position symbols 1701 is displayed in the first color (example: green). In this example, the second detection range 802 is set, and the threshold symbol including the three position symbols 1701 is displayed in the third color (example: orange). In this example, the display of the first detection range 801 is omitted, but the first detection range 801 may be displayed by the threshold symbol. Moreover, the power supply symbol 1904, the first output symbol 1905, and the second output symbol 1906 described above are also displayed. In a case where the cylinder sensor 103 is activated, the display control unit 2516 turns on the power supply symbol 1904. The display control unit 2516 switches on and off the first output symbol 1905 and the second output symbol 1906 or switches the display color on the basis of the output signal output from the cylinder sensor 103.

In FIG. 26, the operation state of the second air cylinder 102 is illustrated on the lower side. “Air cylinder DEF” is displayed as the name of the second air cylinder 102. Moreover, the bar symbol 1801 is displayed to indicate the position of the piston 402. In order to inform the user of the first detection range 801 and the second detection range 802, range symbols 1802 and 1803 are also displayed. Moreover, the power supply symbol 1904, the first output symbol 1905, and the second output symbol 1906 described above are also displayed. The power supply symbol 1904, the first output symbol 1905, and the second output symbol 1906 are switched on and off or switched in display color on the basis of an output signal output from the cylinder sensor 103.

When the operation states of the plurality of air cylinders 102 are displayed as described above, different screen templates 2522 may be adopted, or the same screen template 2522 may be adopted. A screen template 2522 desired by the user among the plurality of screen templates 2522 may be selected through the setting screen according to the application of the air cylinder 102 to be displayed.

Since the display region of the display panel 105 is much wider than the display region of the relay amplifier 104 and the display region of the air cylinder 102, more information can be displayed. On the other hand, when a UI similar to the UI of the relay amplifier 104 or the UI of the air cylinder 102 is adopted for the display panel 105, the user can immediately grasp the operation status.

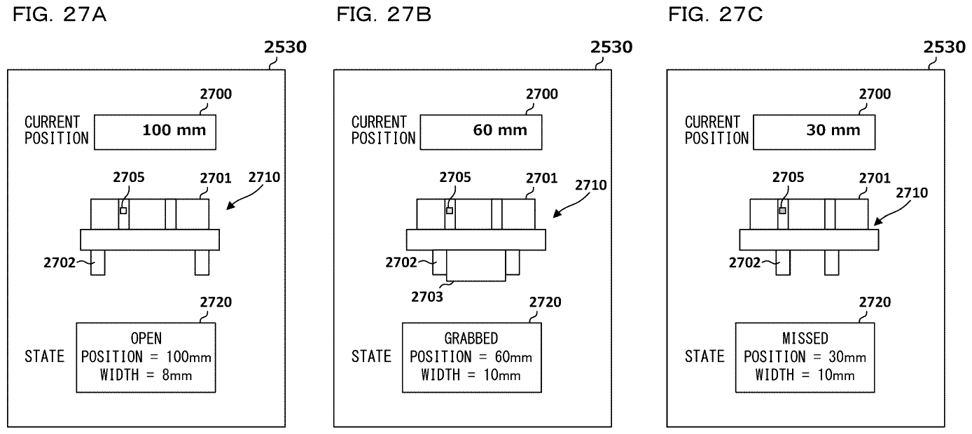

FIGS. 27A to 27C illustrate other operation screens. A chuck (gripper, robot hand) may be adopted as a control target of the air cylinder 102. The display control unit 2516 displays an operation screen according to the screen template 2522 on the OLED display 2530. The screen template 2522 may have a current value display region 1700, an operation display region 1710, and a state display region 2720. The current value display region 1700 displays the current position (current value) of the piston 402 indicated by the output signal output from the cylinder sensor 103. The operation display region 1710 displays a chuck 2701, a claw 2702, and an output symbol 2705. The chuck 2701 is an icon imitating a chuck to be controlled by the air cylinder 102. The claw 2702 is an icon imitating a plurality of claws for gripping a workpiece 2703 to be gripped. The workpiece 2703 is, for example, a product or a part manufactured in a manufacturing line. The output symbol 2705 is a symbol (indicator) indicating in which detection range of the plurality of detection ranges set in advance the claw 2702 is located. The state display region 2720 indicates an image or a character indicating the current state of the chuck 2701, and a detection range (a threshold and a width).

FIG. 27A illustrates a state in which the first output signal is output from the cylinder sensor 103. In this example, the current position indicates a distance between the two claws 2702. The first detection range 801 that defines a condition under which the first output signal is output is defined by a threshold of 100 mm and a width of 8 mm. Therefore, in a case where the current position is 96 mm or more and 104 mm or less, the cylinder sensor 103 outputs the first output signal. While the first output signal is output, the output symbol 2705 is displayed in a color (example: blue) corresponding to the first output signal.

FIG. 27B illustrates a state in which the second output signal is output from the cylinder sensor 103. The second detection range 802 that defines a condition under which the second output signal is output is defined by a threshold of 60 mm and a width of 10 mm. Therefore, in a case where the current position is 50 mm or more and 70 mm or less, the cylinder sensor 103 outputs the second output signal. While the second output signal is being output, the output symbol 2705 is displayed in a color (example: orange) corresponding to the second output signal.

FIG. 27C illustrates a state in which the third output signal is output from the cylinder sensor 103. A third detection range that defines a condition under which the third output signal is output is defined by a threshold of 30 mm and a width of 10 mm. Therefore, in a case where the current position is 20 mm or more and 40 mm or less, the cylinder sensor 103 outputs the third output signal. While the third output signal is being output, the output symbol 2705 is displayed in a color (example: purple) corresponding to the third output signal.

### 12-3. Setting Screen

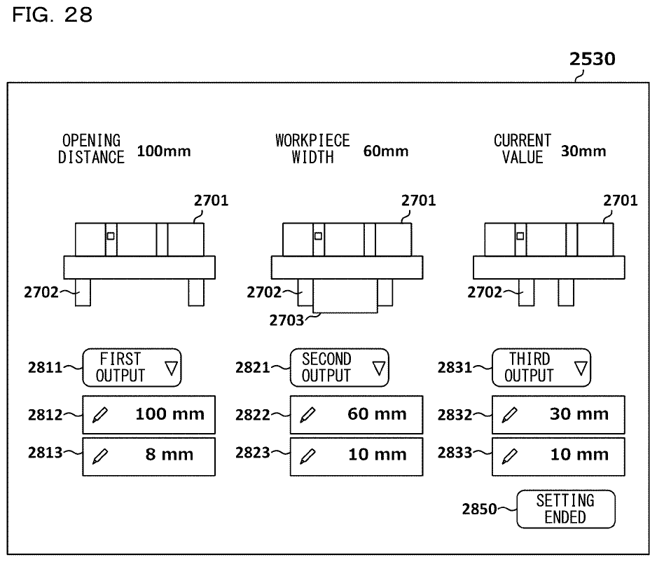

FIG. 28 illustrates an example of a setting screen displayed on the OLED display 2530 of the display panel 105. The display control unit 2516 displays the setting screen on the OLED display 2530 in accordance with the screen template 2522. The signal selection units 2811, 2821, and 2831 are pull-down lists or the like for selecting one output signal from among a plurality of output signals. The threshold input units 2812, 2822, and 2832 are input units for inputting thresholds. When the user touches the threshold input units 2812, 2822, and 2832 with a finger or a touch pen (stylus), the OLED display 2530 may assist the user to input a numerical value by displaying a numeric keypad screen or a numerical value up/down adjustment key. Alternatively, the numerical values displayed on the threshold input units 2812, 2822, and 2832 may change in conjunction with the position information of the piston 402 output from the cylinder sensor 103. In this case, the user may open or close the two claws 2702 instead of inputting a numerical value with a finger. The display control unit 2516 may change the numerical values displayed on the threshold input units 2812, 2822, and 2832 on the basis of the position information output from the cylinder sensor 103 according to the position of the claw 2702. As a result, the user can decide a threshold considered to be appropriate by operating the claw 2702.

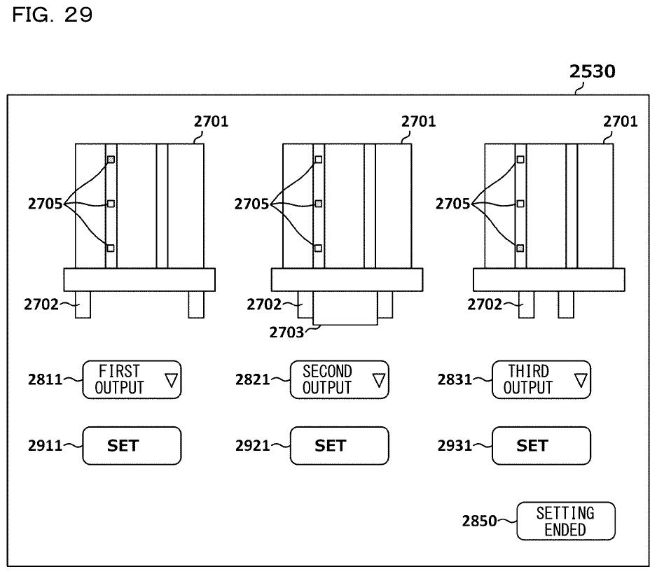

FIG. 29 illustrates another example of the setting screen displayed on the OLED display 2530 of the display panel 105. In this example, the display panel 105 can receive the position information output from the cylinder sensor 103, but does not display the position information.

The user selects the first output signal by operating the signal selection unit 2811, moves the two claws 2702 with a finger, and stops the two claws 2702 at a position corresponding to the threshold of the first output signal. When a set button 2911 is pressed, the setting unit 2513 decides the current position of the claw 2702 as the threshold corresponding to the first output signal, and stores the threshold in the setting information.

The user selects the second output signal by operating the signal selection unit 2821, moves the two claws 2702, and stops the two claws 2702 at a position corresponding to the threshold of the second output signal. The workpiece 2703 may be sandwiched between the two claws 2702. When the set button 2921 is pressed, the setting unit 2513 decides the current position of the claw 2702 as the threshold corresponding to the second output signal, and stores the threshold in the setting information.

The user operates the signal selection unit 2831 to select the third output signal, moves the two claws 2702, and stops the two claws 2702 at a position corresponding to the threshold of the third output signal. In this case, two claws 2702 are positioned at positions corresponding to a missing state. When the set button 2931 is pressed, the setting unit 2513 decides the current position of the claw 2702 as the threshold corresponding to the third output signal, and stores the threshold in the setting information.

The setting unit 2513 writes the setting information in the cylinder sensor 103 via the valve system 101 and the relay amplifier 104. As a result, the cylinder sensor 103 may be set through the display panel 105.

### 12-4. Flowchart

### 12-4-1. Operation Screen

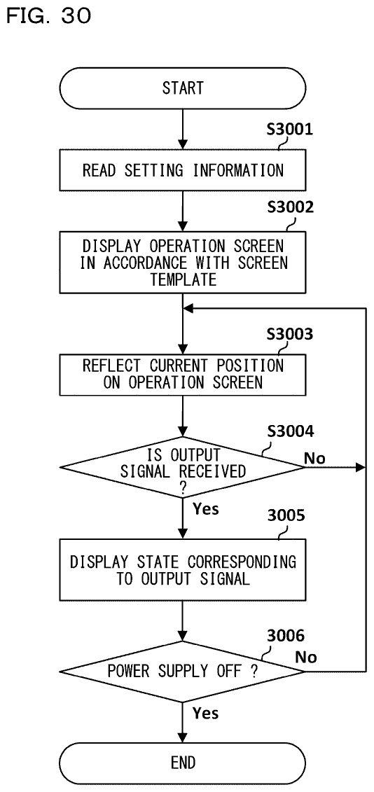

FIG. 30 illustrates a display control method of the operation screen executed by the CPU 2501 of the display panel 105 in accordance with the control program 2521.

In S3001, the CPU 2501 (display control unit 2516) reads the setting information from the memory 2502.

In S3002, the CPU 2501 (display control unit 2516) reads the screen template 2522 designated by the setting information, and displays the operation screen on the OLED display 2530 in accordance with the screen template 2522. In a case where the setting information does not exist, the display control unit 2516 may select a screen template 2522 desired by the user from among the plurality of screen templates 2522.

In S3003, the CPU 2501 displays the current position indicated by the position information output from the cylinder sensor 103 on the operation screen. As illustrated in FIG. 26, the display control unit 2516 changes the display color of the position symbol 1701 corresponding to the current position, displays the bar symbol 1801 with the length corresponding to the current position, displays the current position in the current position display region 2700, or displays the claw 2702 at the position corresponding to the current position.

In S3004, the CPU 2501 (display control unit 2516) determines whether an output signal has been received from the cylinder sensor 103. When the piston 402 or the claw 2702 is located within a preset detection range, the cylinder sensor 103 outputs an output signal corresponding to the detection range. When the output signal is not output, the CPU 2501 returns from S3004 to S3003. When the output signal is output, the CPU 2501 proceeds from S3004 to S3005.

In S3005, the CPU 2501 (display control unit 2516) displays a state corresponding to the output signal on the OLED display 2530. For example, as illustrated in FIG. 26, when the first output signal is output, the display control unit 2516 changes the output symbol 1905 to a predetermined display color. When the second output signal is output, the display control unit 2516 changes the output symbol 1906 to a predetermined display color. As illustrated in FIG. 27A, when the first output signal is output, the display control unit 2516 changes the output symbol 2705 to the display color corresponding to the first output signal. The display control unit 2516 may display a message, a threshold, a width, and the like corresponding to the first output signal in the state display region 2720. As illustrated in FIG. 27B, when the second output signal is output, the display control unit 2516 changes the output symbol 2705 to the display color corresponding to the second output signal. The display control unit 2516 may display a message, a threshold, a width, and the like corresponding to the second output signal in the state display region 2720. As illustrated in FIG. 27C, when the third output signal is output, the display control unit 2516 changes the output symbol 2705 to the display color corresponding to the third output signal. The display control unit 2516 may display a message, a threshold, a width, and the like corresponding to the third output signal in the state display region 2720.

In S3006, the CPU 2501 determines whether power supply OFF is instructed. When power supply OFF is not instructed, the CPU 2501 returns from S3006 to S3003. When power supply OFF is instructed, the CPU 2501 ends the display control method and shuts down.

### 12-4-2. Setting Screen

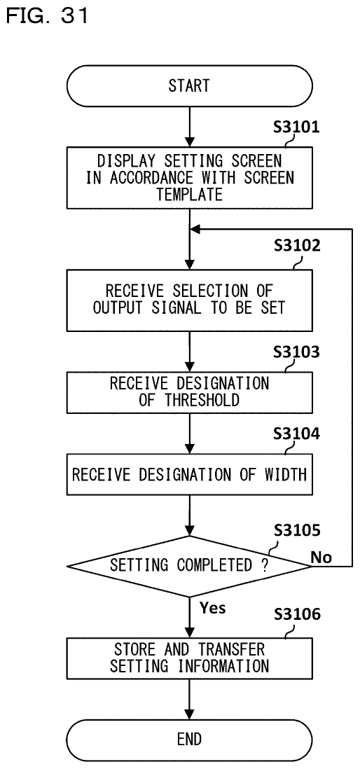

FIG. 31 illustrates a display control method of the operation screen executed by the CPU 2501 of the display panel 105 in accordance with the control program 2521. When the touch sensor 2505 detects a setting start trigger (predetermined operation by the user), the CPU 2501 starts the setting processing in accordance with the control program 2521.

In S3101, the CPU 2501 (display control unit 2516) displays the setting screen on the OLED display 2530 in accordance with the screen template 2522 for the setting screen. The setting screen may be one illustrated in FIG. 28 or may be one illustrated in FIG. 29. Alternatively, the CPU 2501 may receive designation of a setting screen desired by the user among the plurality of setting screens, and display the setting screen designated by the user on the OLED display 2530.

In S3102, the CPU 2501 (setting unit 2513) receives selection of an output signal to be set. For example, the setting unit 2513 receives selection of an output signal by the user from an output signal list displayed on the signal selection unit 2811.

In S3103, the CPU 2501 (setting unit 2513) receives designation of a threshold for defining the detection range. For example, the range setting unit 2534 receives a numerical value input in the threshold input unit 2812 as the threshold. For example, the range setting unit 2534 may receive the current value output from the cylinder sensor 103 as the threshold.

In S3104, the CPU 2501 (setting unit 2513) receives designation of a width for defining the detection range. For example, the width setting unit 2535 may receive a numerical value input to a width input unit 2813 as the width. The width setting unit 2535 may cyclically switch the width according to a tap input to the touch sensor 2505.

In step S3105, the CPU 2501 (setting unit 2513) determines whether setting completion has been instructed through the touch sensor 2505. For example, when the touch sensor 2505 detects that the setting completion button 2850 is touched, the setting unit 2513 may determine that the setting completion is instructed. When the setting completion is not instructed, the CPU 2501 returns to S3102 and receives the setting for the next output signal. When the setting completion is instructed, the CPU 2501 proceeds to S3106.

In S3106, the CPU 2501 (setting unit 2513) creates setting information associating the output signal with the detection range (threshold and width), stores the setting information in the memory 2502, and transfers the setting information to the cylinder sensor 103.

### 16. Setting Function in Relay Amplifier

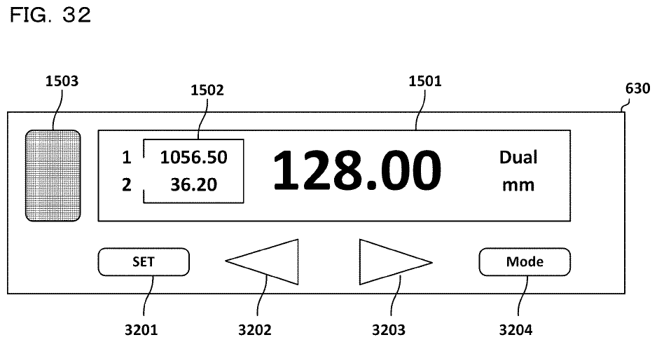

FIG. 32 illustrates another example of the relay amplifier 104. The relay amplifier 104 includes a set button 3201, a leftward button 3202, a rightward button 3203, and a mode button 3204. Each of these buttons is configured to turn on/off the corresponding operation switch 605, and the CPU 601 monitors on/off states of the plurality of operation switches 605.

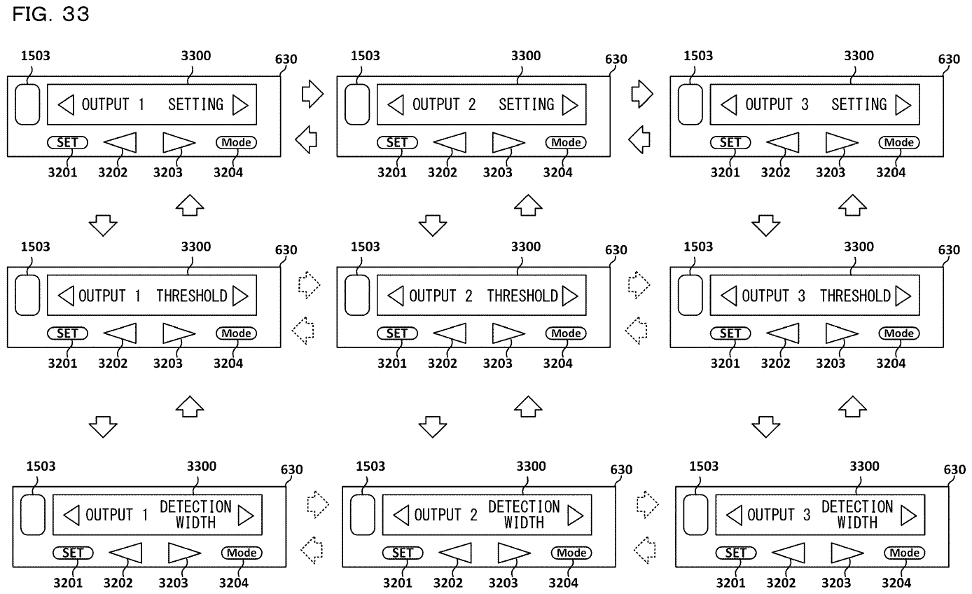

FIG. 33 illustrates a setting screen for setting the cylinder sensor 103. When detecting that the mode button 3204 is long-pressed, the setting unit 613 is activated. The setting unit 613 instructs the display control unit 616 to display the setting screen, and the display control unit 616 displays a setting screen 3300 on the OLED display 630 in accordance with a screen template 622. According to this example, a case where there are three output signals is assumed. However, the number of output signals may be one or more. As illustrated in FIG. 33, first, a screen of “output 1 setting” is displayed. This means that the setting is for the first output signal. When the rightward button 3203 is pressed in this state, the OLED display 630 displays a setting screen of “output 2 setting”. This means that the setting is for the second output signal. When the rightward button 3203 is further pressed in this state, the OLED display 630 displays a setting screen of “output 3 setting”. This means that the setting is for the third output signal. When the rightward button 3203 is pressed in this state, the OLED display 630 displays a setting screen of “output 1 setting”. Note that, in a case where the fourth output signal exists, the OLED display 630 displays a setting screen of “output 4 setting”.

When the short press of the mode button 3204 is detected while the setting screen of “output 1 setting” is displayed, the display control unit 616 displays a setting screen of “output 1 threshold” on the OLED display 630. This means that the threshold of the detection range that is a condition for outputting the first output signal is set. When further short press of the mode button 3204 is detected in this state, the display control unit 616 displays a setting screen of “output 1 detection width” on the OLED display 630. This means that the width of the detection range that is a condition for outputting the first output signal is set.

When the short press of the mode button 3204 is detected while the setting screen of “output 2 setting” is displayed, the display control unit 616 displays a setting screen of “output 2 threshold” on the OLED display 630. This means that the threshold of the detection range that is a condition for outputting the second output signal is set. When further short press of the mode button 3204 is detected in this state, the display control unit 616 displays a setting screen of “output 2 detection width” on the OLED display 630. This means that the width of the detection range that is a condition for outputting the second output signal is set. Note that, when the short press of the rightward button 3203 is detected while the setting screen of “output 1 threshold” is displayed, the display control unit 616 may display a setting screen of “output 2 threshold” on the OLED display 630. When the short press of the rightward button 3203 is detected while the setting screen of “output 1 detection width” is displayed, the display control unit 616 may display a setting screen of “output 2 detection width” on the OLED display 630. When the leftward button 3202 is pressed, the original screen may be displayed.

When the short press of the mode button 3204 is detected while the setting screen of “output 3 setting” is displayed, the display control unit 616 displays a setting screen of “output 3 threshold” on the OLED display 630. This means that the threshold of the detection range that is a condition for outputting the third output signal is set. When further short press of the mode button 3204 is detected in this state, the display control unit 616 displays a setting screen of “output 3 detection width” on the OLED display 630. This means that the width of the detection range that is a condition for outputting the third output signal is set. Note that, when the short press of the rightward button 3203 is detected while the setting screen of “output 2 threshold” is displayed, the display control unit 616 may display a setting screen of “output 3 threshold” on the OLED display 630. When the short press of the rightward button 3203 is detected while the setting screen of “output 2 detection width” is displayed, the display control unit 616 may display a setting screen of “output 3 detection width” on the OLED display 630. When the leftward button 3202 is pressed, the original screen may be displayed.

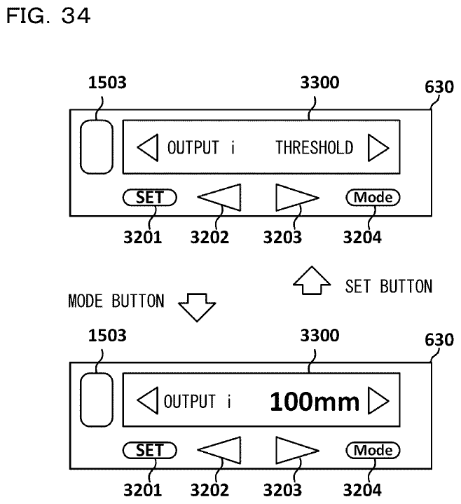

FIG. 34 illustrates a state in which the threshold of the i-th output signal is set. i is an integer such as 1, 2, or 3. When the long press of the mode button 3204 is detected while the screen of “output i threshold” is displayed, the display control unit 616 displays a screen of “output i numerical value +unit”. Here, the numerical value is an initial value or a previously set value. The unit is an initial value or a previously set unit. The unit may be fixed. The user short-presses the leftward button 3202 or the rightward button 3203 to set a threshold for defining the detection range. The display control unit 616 may decrease the numerical value every time the short press of the leftward button 3202 is detected. The display control unit 616 may increase the numerical value every time the short press of the rightward button 3203 is detected. When detecting that the set button 3201 is pressed, the range setting unit 634 decides the currently displayed numerical value as the threshold of the i-th detection range and stores the threshold in the setting information. When the setting is completed by pressing the set button 3201, the display control unit 616 returns to the screen of “output i threshold” which is the original screen. Note that confirmation of a numerical value and completion of setting may be instructed by the long press of the mode button 3204 instead of the set button 3201.

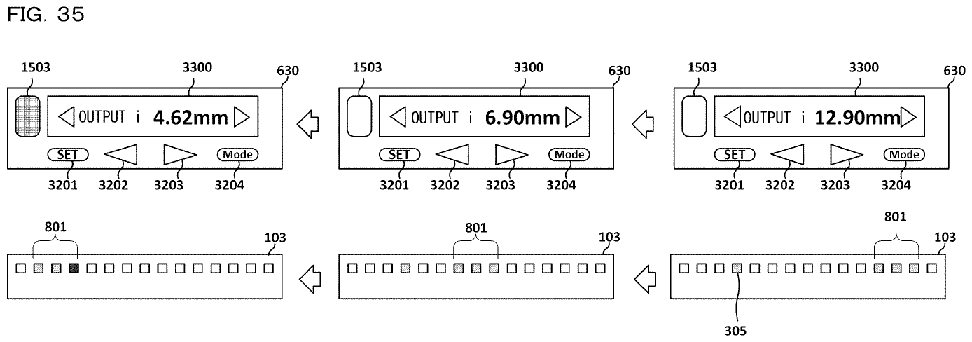

FIG. 35 illustrates cooperation between the setting screen displayed on the relay amplifier 104 and the symbol displayed on the cylinder sensor 103. The setting unit 613 may transmit the threshold displayed on the setting screen to the cylinder sensor 103 in real time. At this time, the setting unit 613 may also transmit the previously set width to the cylinder sensor 103. The CPU 501 of the cylinder sensor 103 turns on the plurality of LEDs 305 corresponding to the threshold and the width received from the relay amplifier 104. According to this example, since the threshold is 12.90 mm, the second, third, and fourth LEDs 305 from the right among the plurality of LEDs 305 are turned on. Note that the CPU 501 may also turn on the LED 305 corresponding to the current position of the piston 402. As a result, the user can set the detection range with the current position of the piston 402 as a guide.

The threshold reaches 6.90 mm when the user short-presses the leftward button 3202 several times. Since the setting unit 613 transmits the threshold displayed on the setting screen to the cylinder sensor 103 in real time, the LEDs 305 to be turned on in the cylinder sensor 103 also gradually shift to the LEDs 305 on the left. According to FIG. 35, in a case where the threshold is 6.90 mm, the seventh, eighth, and ninth LEDs 305 from the right are turned on.

The threshold reaches 4.62 mm when the user short-presses the leftward button 3202 several times. Since the setting unit 613 transmits the threshold displayed on the setting screen to the cylinder sensor 103 in real time, the LEDs 305 to be turned on in the cylinder sensor 103 also gradually shift to the LEDs 305 on the left. According to FIG. 35, in a case where the threshold is 4.62 mm, the twelfth, thirteenth, and fourteenth LEDs 305 from the right are turned on. Note that the current position of the piston 402 is a position corresponding to the twelfth LED 305. Therefore, the display control unit 516 may turn on the twelfth LED 305 in a color that means both the detection range 801 and the current position of the piston 402.

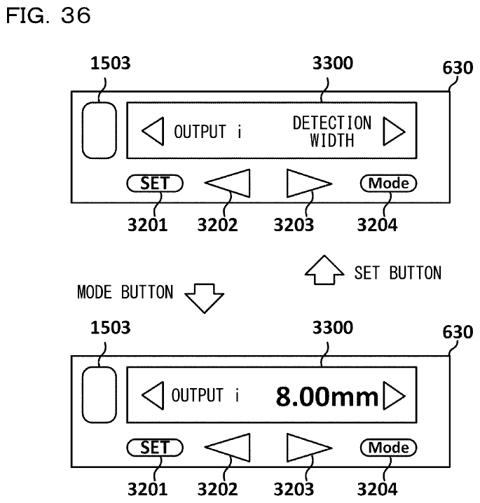

FIG. 36 illustrates a state in which the detection width of the i-th output signal is set. i is an integer such as 1, 2, or 3. When the long press of the mode button 3204 is detected while the screen of “output i detection width” is displayed, the display control unit 616 displays a screen of “output i numerical value +unit”. Here, the numerical value is an initial value or a previously set value. The unit is an initial value or a previously set unit. The unit may be fixed. The user short-presses the leftward button 3202 or the rightward button 3203 to set a width for defining the detection range. The display control unit 616 decreases the numerical value every time the short press of the leftward button 3202 is detected. The display control unit 616 increases the numerical value each time the short press of the rightward button 3203 is detected. When detecting that the set button 3201 is pressed, the range setting unit 634 decides the currently displayed numerical value as the width of the i-th detection range and stores the width in the setting information. When the setting is completed by pressing the set button 3201, the display control unit 616 returns to the screen of “output i detection width” which is the original screen. Note that confirmation of a numerical value and completion of setting may be instructed by the long press of the mode button 3204 instead of the set button 3201.

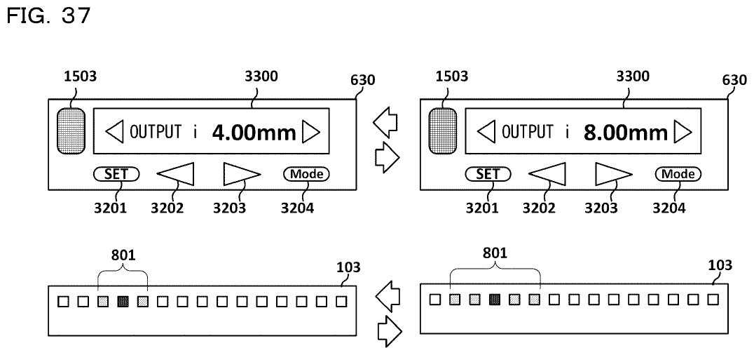

FIG. 37 illustrates cooperation between the setting screen displayed on the relay amplifier 104 and the symbol displayed on the cylinder sensor 103. The setting unit 613 may transmit the width displayed on the setting screen to the cylinder sensor 103 in real time. At this time, the setting unit 613 may also transmit the previously set threshold to the cylinder sensor 103. The CPU 501 of the cylinder sensor 103 turns on the plurality of LEDs 305 corresponding to the threshold and the width received from the relay amplifier 104. In this example, since the threshold is 4.20 mm and the width is 4 mm, the eleventh, twelfth, and thirteenth LEDs 305 from the right among the plurality of LEDs 305 are turned on. Note that the CPU 501 may also turn on the LED 305 corresponding to the current position of the piston 402.

When the user short-presses the leftward button 3202 or the rightward button 3203, the display control unit 616 cyclically switches the width between 4 mm and 8 mm. When the width is set to 8.00 mm, among the plurality of LEDs 305, the eleventh to fourteenth LEDs 305 from the right are turned on. As described above, the setting operation in the relay amplifier 104 and the display of the symbol in the cylinder sensor 103 may be linked.

In the above-described embodiment, the setting is completed by pressing the set button 3201, but the setting may be completed by the long press of the mode button 3204. In this case, the set button 3201 may function as an immediate setting reflection button that transmits the set numerical value to the cylinder sensor 103 in real time and causes the cylinder sensor 103 to use the numerical value.

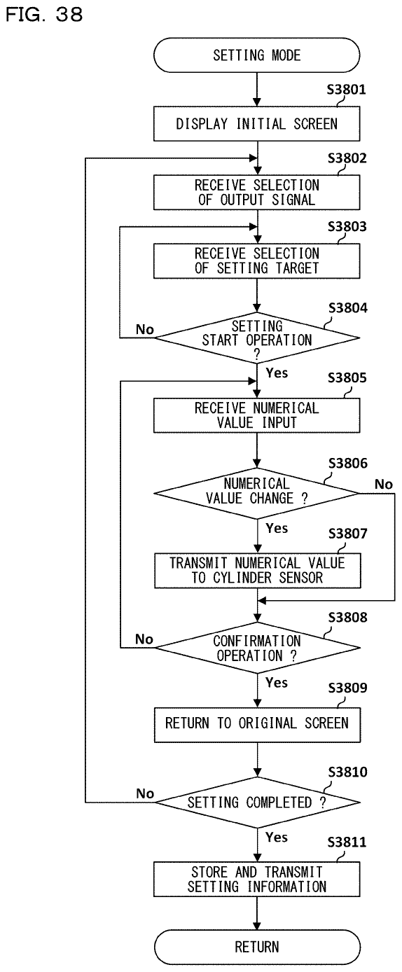

FIG. 38 is a flowchart illustrating a setting method executed in the relay amplifier 104 by the CPU 601 in accordance with the control program 621. When detecting the long press of the mode button 3204, the CPU 601 transitions from the operation mode to the setting mode. At this time, the CPU 601 may instruct the cylinder sensor 103 to transition from the operation mode to the setting mode.

In S3801, the CPU 601 (setting unit 613 and display control unit 616) displays an initial screen on the OLED display 630. As suggested by FIG. 33, the initial screen may be a selection screen of an output signal. Alternatively, the initial screen may be a top screen prepared separately.

In S3802, the CPU 601 (setting unit 613 and display control unit 616) receives the selection of the output signal. As suggested by FIG. 33, the user operates the leftward button 3202, the rightward button 3203, and the mode button 3204 to select a desired output signal from the plurality of output signals. The display control unit 616 displays a setting screen for the selected output signal on the OLED display 630.

In S3803, the CPU 601 (setting unit 613 and display control unit 616) receives selection of a setting target. As suggested by FIG. 33, the user operates the leftward button 3202, the rightward button 3203, and the mode button 3204 to select a threshold or width. A lighting color or a display color of each detection range may be selected as a setting target. As described above, the selection target may be a parameter other than the threshold or the width.

In S3804, the CPU 601 (setting unit 613) determines whether a setting start operation has been input. The setting start operation may be, for example, the long press of the mode button 3204. As suggested by FIGS. 34 and 36, when the long press of the mode button 3204 is detected, the CPU 601 proceeds from S3804 to S3805. When the long press of the mode button 3204 is not detected, the CPU 601 returns from S3804 to S3803.

In S3805, the CPU 601 (setting unit 613 and display control unit 616) displays the setting screen of the selected setting target on the OLED display 630, and receives a numerical value input. The setting screen is a setting screen of the threshold or a setting screen of the width. Therefore, the input numerical value is a threshold or a width. The numerical value may be input by the rightward button 3203 or the leftward button 3202, for example.

In S3806, the CPU 601 (setting unit 613) determines whether the numerical value has been changed. When the numerical value is changed by the leftward button 3202 or the rightward button 3203, the CPU 601 proceeds from S3806 to S3807. When the numerical value has not been changed, the CPU 601 proceeds from S3806 to S3808.

In S3807, the CPU 601 (setting unit 613) transmits the numerical value set by the user to the cylinder sensor 103 through the communication circuit 604. When receiving the numerical value, the CPU 501 (display control unit 516) of the cylinder sensor 103 reflects the received numerical value on the symbol displayer 505. As described above, the plurality of LEDs 305 corresponding to the received threshold and width is turned on.

In S3808, the CPU 601 (setting unit 613) determines whether a confirmation operation has been input. The confirmation operation may be, for example, pressing down of the set button 3201. When the confirmation operation has not been input, the CPU 601 returns from S3808 to S3805. When the confirmation operation has been input, the CPU 601 proceeds from S3808 to S3809.

In S3809, the CPU 601 (setting unit 613 and display control unit 616) returns from the setting screen of the numerical value to the original screen (signal selection screen). During the transition from the setting screen to the original screen, the display control unit 616 may display, on the OLED display 630, a confirmation symbol indicating that the set value has been confirmed.

In S3810, the CPU 601 (setting unit 613) determines whether a setting completion operation has been input. The setting completion operation may be, for example, the long press of the mode button 3204. When the setting completion operation has not been input, the CPU 601 returns from S3810 to S3802. When the setting completion operation has been input, the CPU 601 proceeds from S3810 to S3811.

In S3811, the CPU 601 (setting unit 613) stores, in the memory 602, the setting information including the threshold and the width input for each output signal through the setting screen, and transmits the setting information to the cylinder sensor 103. When receiving the setting information, the cylinder sensor 103 stores the setting information in the memory 502.

### 13. Setting Method in Display Panel

Although FIGS. 32 to 38 mainly illustrate the setting method in the relay amplifier 104, this is merely an example. FIGS. 32 to 38 may be understood as a setting method in the display panel 105. In this case, the set button 3201, the leftward button 3202, the rightward button 3203, and the mode button 3204 are button objects displayed on the OLED display 2530, and may be implemented as button objects whose touch is detected by the touch sensor 2505. Moreover, the processing by the CPU 601 described with reference to FIGS. 32 to 38 may be read as processing by the CPU 2501. The OLED display 630 is read as an OLED display 2530. Reference numerals of other constituent terms are similarly read.

Moreover, since the display panel 105 can directly or indirectly communicate with the cylinder sensor 103 via the controller 121 and the relay amplifier 104 of the valve system 101, the display of the symbol in the setting mode can also cooperate. Here, the direct communication refers to communication in which an address of the cylinder sensor 103 can be designated as a destination of a communication signal. The indirect communication refers to communication in which information regarding the cylinder sensor 103 can be acquired from a communication apparatus by directly or indirectly communicating with the communication apparatus (examples: the valve system 101, the relay amplifier 104) interposed between the display panel 105 and the cylinder sensor 103. For example, the controller 121 receives the output signal transmitted from the cylinder sensor 103 via the relay amplifier 104, and stores the logic of each output signal in the memory. The display panel 105 may acquire the logic of each output signal by designating a storage region (examples: a variable, a device, an address) associated with each output signal. Note that the output signal may be an analog value.

Even in a case where the display panel 105 transmits the setting information to the cylinder sensor 103, either the direct communication method or the indirect communication method is adopted. In the indirect communication method, the display panel 105 writes the threshold in a storage region secured to store the threshold. When detecting the writing to the storage region, the controller 121 reads the threshold from the region and transmits the threshold to the cylinder sensor 103. Similarly, the display panel 105 writes the width in a storage region secured to store the width of the detection range. When detecting the writing to the storage region, the controller 121 reads the width from the region and transmits the width to the cylinder sensor 103. In this manner, the display panel 105 and the cylinder sensor 103 may indirectly communicate with each other.

### 14. Summary

As illustrated in FIG. 4, the position detection sensor 100 detects the position of the displacement body (example: the piston 402) movable in parallel with the first direction (example: the longitudinal direction of the air cylinder 102). The cylinder sensor 103 is an example of a detection device that generates a detection signal according to the position of the magnet 403 provided in the displacement body. The CPU 501 and the position specification unit 512 are examples of a position specification unit that specifies the position of the displacement body in the first direction on the basis of the detection signal generated by the detection device. As illustrated in FIGS. 2 and 4, the housing 200 is an example of a housing that accommodates at least a part of the detection device and extends along the first direction. The symbol displayer 505 is an example of a display unit that includes a plurality of display elements (examples: the LEDs 305, the display pixels of the OLED display 630) arranged in the housing 200 at positions different from each other along the first direction and displays a symbol indicating a position of the displacement body along the first direction. The CPU 501 and the display control unit 516 are examples of a display control unit that controls the display unit to display in different modes, by displaying symbols at different positions on the plurality of display elements, the first state in which the displacement body exists at the first position (example: a left end of the detectable range) corresponding to one end portion of the displacement range, the second state in which the displacement body exists at the second position (example: a right end of the detectable range) corresponding to the other end portion of the displacement range, and the intermediate state in which the displacement body exists at the intermediate position between the first position and the second position. Note that each of the one end portion and the other end portion may be an outermost position, or may be an inner position rather than the outermost position.

According to the embodiment, not only the first state and the second state but also the intermediate state between the first state and the second state can be displayed, so that installation work of the position detection sensor 100 is facilitated.

As FIGS. 2 and 3 suggest, the external input terminal 503 and the external output terminal 506 are examples of a signal interface unit provided at the end portion of the housing 200. The CPU 501 and the output unit 517 are examples of an output unit that outputs position-related information (examples: an analog value indicating the position of the piston 402, a digital value such as the first output signal and the second output signal) based on the position specified by the position specification unit 512 via the signal interface unit. By outputting the position-related information to the relay amplifier 104 and the valve system 101 in this manner, it is possible to display the position-related information in the relay amplifier 104 and to control the valve 122 on the basis of the position-related information in the valve system 101.

The plurality of display elements may include at least three or more light sources (examples: the LEDs 305, the display pixels of the OLED display 630) arranged along the first direction. The plurality of display elements may include at least four or more light sources (examples: the LEDs 305, the display pixels of the OLED display 630) arranged along the first direction. The display control unit 516 may control the plurality of display elements so as to display, in different modes, an intermediate state in which the displacement body exists at the third position as the intermediate position and another intermediate state in which the displacement body exists at the fourth position as the intermediate position. For example, the display control unit 516 may express the intermediate state in which the displacement body exists at the third position in a first color, and display another intermediate state in which the displacement body exists at the fourth position in a second color.

As illustrated in FIG. 3, the detection device (example: the cylinder sensor 103) may include a plurality of magnetic detection elements (example: the Hall elements 304) arranged along the first direction.

As illustrated in FIG. 3, the plurality of magnetic detection elements may be arranged at a first interval (example: 4 mm or more and 6 mm or less). The plurality of display elements (examples: the LEDs 305, the position image 1701) may be arranged at a second interval shorter than the first interval. For example, the second interval may be less than 10 mm and 1 mm or more. Alternatively, the second interval may be less than 4 mm and 2 mm or more.

As suggested by FIGS. 14A and 14B, the display control unit 516 may display the first state, the second state, and the intermediate state with a variable length bar realized by a plurality of display elements. As illustrated in FIGS. 16A and 16B, and FIG. 18, the display control unit 516 may display the position of the displacement body with the bar symbol 1801.

As suggested by FIGS. 14A and 14B, the display control unit 516 may change the length of the bar by controlling the number of light sources to be turned on among the plurality of light sources (examples: the LEDs 305, the display pixels of the OLED display 630).

The display control unit 516 may control the display unit (examples: the LEDs 305, the OLED display 630) so as to display the first state, the second state, and the intermediate state in different colors. This allows the user to clearly distinguish the three states.

The output unit 517 may output the first output signal when the displacement body is located in the first detection range 801 including the first position, and may output the second output signal when the displacement body is located in the second detection range 802 including the second position.

The setting unit 513 is an example of a teaching unit that executes teaching that is processing of setting the first detection range 801 and the second detection range 802 according to a user's instruction.

As described with reference to FIG. 12, the operation button 202 and the operation switch 303 are examples of the input unit to which the first operation is input. The setting unit 513 may start the setting of the first detection range 801 when the first operation (example: a long press of the operation button 202 for 2 seconds) is input in the input unit. The setting unit 513 may confirm the first detection range 801 on the basis of the first position where the displacement body exists and the predetermined width when the second operation (example: a long press of the operation button 202 for 2 seconds) is input in the input unit.

When the first operation is input in the input unit after the first detection range 801 is confirmed, the setting unit 513 may start setting the second detection range 802. The setting unit 513 may confirm the second detection range 802 on the basis of the second position where the displacement body exists and the predetermined width when the second operation is input in the input unit. Note that the confirmation operation of the first detection range 801 may also be used as the setting start operation of the second detection range 802. As a result, the user can continuously set the first detection range 801 and the second detection range 802.

Meanwhile, the number of detection ranges and the number of output signals may be three or more. The output unit 517 may output the third output signal when the displacement body is located in the third detection range including the third position. When the first operation is input in the input unit after the second detection range is confirmed, the setting unit 513 may start setting the third detection range. The setting unit 513 may confirm the third detection range on the basis of the third position where the displacement body exists and the predetermined width when the second operation is input in the input unit. As a result, so-called three-point output may be realized. Here, the three-point output means that an output signal according to three positions of the displacement body is output. For example, in a case where the displacement body is a gripper (chuck) that grabs an object or releases an object, a state in which two claws open, a state in which two claws grab an object, and a state in which two claws fail to grab an object (missing state) may be realized by the position of the piston 402 that opens and closes the claws. In this case, three detection ranges and three output signals corresponding thereto are set in order to identify the three states.

The setting unit 513 may include the width setting unit 515 that sets a predetermined width according to an instruction input from the input unit. As described with reference to FIGS. 14A and 14B, the width setting unit 515 may switch the width every time the operation button 202 is short-pressed in the setting mode.

As described with reference to FIG. 13, when the first operation is input in the input unit, the setting unit 513 may reset (delete in bulk) the first detection range 801 and the second detection range 802. By resetting the detection range by such a simple operation, the reset work becomes easy.

The symbol displayer 505 may further include the first display element (example: the first output LED 205) indicating that the first output signal is output and the second display element (example: the second output LED 206) indicating that the second output signal is output.

As illustrated in FIGS. 8A to 8C and the like, the symbol displayer 505 may change the position of the symbol suggesting the position of the displacement body in conjunction with the movement of the displacement body. This facilitates installation work of the cylinder sensor 103.

The detection device (example: the cylinder sensor 103) may be operated by being supplied with power via a relay apparatus (example: the relay amplifier 104) installed between a moving apparatus (example: the valve system 101) that moves the displacement body and the housing 200.

As illustrated in FIG. 3, the housing 200 is an example of a first housing that accommodates at least a part of the detection device and extends along the first direction. The housing 1900 of the relay amplifier 104 and the housing 2500 of the display panel 105 are examples of a second housing connected to the first housing via a cable (examples: the IO-Link cable, the Ethernet cable). The operation switch 605 and the touch sensor 2505 are examples of an input unit that is provided in the second housing and receives an operation input. The OLED displays 630 and 2530 are examples of a display unit that is provided in the second housing, includes a plurality of display elements (example: display pixels) arranged in the second housing at positions different from each other along a second direction corresponding to the first direction, and displays a position symbol indicating a position of the displacement body along the first direction and a threshold symbol indicating a position of a threshold. The display control units 616 and 2516 may be provided in the second housing, and may control the display unit so as to display in different modes, by displaying the position symbol at different positions on the plurality of display elements, a first state in which the displacement body exists at a first position corresponding to one end portion of the displacement range, a second state in which the displacement body exists at a second position corresponding to the other end portion of the displacement range, and an intermediate state in which the displacement body exists at an intermediate position between the first position and the second position, and may control the display unit so as to display the threshold symbol at different positions on the plurality of display elements in accordance with the threshold set according to the operation input received via the input unit. This facilitates installation work of the position detection sensor 100.

The plurality of display elements may include at least three or more light sources (example: the display pixels of the OLED displays 630 and 2530) arranged along the first direction. The plurality of display elements may include at least four or more light sources (example: the display pixels of the OLED displays 630 and 2530) arranged along the first direction. The display control units 616 and 2516 may display, in different modes, an intermediate state in which the displacement body exists at the third position as the intermediate position and another intermediate state in which the displacement body exists at the fourth position as the intermediate position. As illustrated in FIG. 19A, the number of position symbols 1701 may be four or more. For example, the N position symbols 1701 may distinguishably display the N positions.

The display control units 616 and 2516 may control the display unit to display the first state, the second state, and the intermediate state with a variable length bar (example: the bar symbol 1801) realized by a plurality of display elements. Since the OLED displays 630 and 2530 include a large number of display pixels, the bar symbol 1801 can be displayed. The bar symbol 1801 can display the position of the piston 402 in more detail compared to the plurality of LEDs 305.

The plurality of display elements may be a plurality of light sources (display pixels). The display control units 616 and 2516 may change the length of the bar by controlling the number of light sources to be turned on among the plurality of light sources.

As illustrated in FIGS. 20A to 20C and FIGS. 28A to 28C, the display control units 616 and 2516 may display a setting screen for setting a threshold according to an operation input received via the input unit. As illustrated in FIGS. 20A to 20C, 28A to 28C, and 29A to 29C, the display control units 616 and 2516 may control the display unit to display the first state, the second state, and the intermediate state in different modes on the setting screen.

The second housing (examples: the housings 1900 and 2500) may further include a storage unit (examples: memories 602 and 2502) that stores screen template information (examples: screen templates 622 and 2522) for displaying the setting screen. The display control units 616 and 2516 may read the screen template information from the storage unit and display the setting screen on the display unit.

The second housing (examples: the housings 1900 and 2500) may further include a power supply unit (examples: the power supply terminals 607 and 2507) that supplies power to the first housing.

The output unit 517 may output the output signal in a case where the position of the displacement body exceeds the threshold. For example, the output unit 517 may output the output signal when the displacement body is located within the detection range determined by the threshold and the width.

The setting units 613 and 2513 may function as teaching units that execute teaching that is processing of setting a threshold according to a user's instruction. The output unit 517 may be configured to output the output signal when the displacement body is located in the detection range determined by the threshold and the width. The second housing may further include width setting units 635 and 2535 that adjust the width.

The first housing (example: the housing 200) may further include: a second display unit (example: the LED 305) that includes the plurality of display elements arranged in the first housing at positions different from each other along the first direction and displays the position symbol and the threshold symbol; and a second display control unit (example: the display control unit 516) that controls the second display unit to display in different modes, by displaying the position symbol at different positions on the plurality of display elements of the second display unit, the first state, the second state, and the intermediate state, and controls the second display unit to display the threshold symbol at different positions on the plurality of display elements of the second display unit. As described above, the air cylinder 102, the relay amplifier 104, and the display panel 105 each display the position of the piston 402 of the air cylinder 102. Therefore, the display content displayed on the display unit (examples: the OLED displays 630 and 2530) provided in the second housing and the display content displayed on the second display unit (example: the LED 305) can be linked.

The CPU 501 (position specification unit 512, display control unit 616, or output unit 517) may function as a determination unit that generates determination information (example: an output signal indicating whether the current position of the displacement body is included in the detection range) on the basis of the position of the displacement body (examples: the piston 402, the claw 2702) along the first direction and the preset detection range (examples: the first detection range 801, the second detection range 802), or may include the determination unit. The CPUs 501 and 601 and the setting units 513 and 613 are examples of a setting unit in which the positions (example: the thresholds) of the first region (example: the first detection range 801) and the second region (example: the second detection range 802) set as the detection ranges are adjustable, and at least one of the number or the width of the detection ranges is adjustable. As a result, installation work of the position detection sensor 100 becomes easy. Note that the number of detection ranges is changed according to how many detection ranges are set in the setting mode. Moreover, it is possible to increase the variety of the workpiece 2703 that can be gripped by the chuck 2701. That is, by adjusting the width of the detection range according to the size of the workpiece 2703 gripped by the chuck 2701, the chuck 2701 can grip the workpiece 2703 more reliably. The chuck 2701 may be employed to inspect the size of the workpiece 2703. In this case, depending on whether the positions of the two claws 2702 of the chuck 2701 when the workpiece 2703 is gripped are included in the detection range, the CPU 501 outputs an output signal indicating inspection success or an output signal indicating failure. In a case where the tolerance required for the workpiece 2703 is strict, the detection range may be set to be narrower. In the air cylinder 102 in which the stroke (displaceable range) of the piston 402 is short, the piston 402 can be positioned with higher accuracy by setting the detection range to be narrower.

The symbol displayer 505 and the OLED displays 630 and 2530 are examples of a display unit that displays the position of the displacement body along the first direction and the detection range. As shown in the above-described embodiment, the display unit may graphically display the position of the displacement body and the detection range. Graphically displaying means a display mode that allows the user to understand the position of the displacement body and the detection range by symbols without relying only on characters and numerical values.

The housing 200 is an example of a first housing that accommodates the detection device, the position specification unit, and the determination unit. The housings 1900 and 2500 are examples of a second housing including the setting unit. In this case, the display unit (examples: the OLED displays 630 and 2530) is provided in the second housing.

The second housing (example: the housing 1900) may be a housing of a relay apparatus (example: the relay amplifier 104) connected to the first housing via a cable (example: the IO-Link cable 113) and also connected to a control apparatus that controls the displacement body via another cable (example: the IO-Link cable 112).

The display unit (example: the OLED display 2530) may be a display panel 105 connected to a specific communication port 123 provided in a control apparatus (example: the controller 121 of the valve system 101) that controls the displacement body.

The output units 517 and 617 are examples of an output unit that outputs a predetermined output signal when the position of the displacement body is included in the detection range. The setting units 613 and 2513 may set a threshold and a width for defining the detection range.

As illustrated in FIGS. 28, 29, and 33, the setting units 613 and 2513 may set, as the detection ranges, the first region for detecting whether or not the displacement body exists at the first position within the displacement range, the second region for detecting whether or not the displacement body exists at the second position within the displacement range, and the third region for detecting whether or not the displacement body exists at the intermediate position between the first position and the second position.

The displacement body may be a plurality of claws 2702 provided on the chuck 2701 to grip the workpiece 2703. For example, as illustrated in FIGS. 28 and 29, the first position may be a position where the plurality of claws is opened. The second position may be a position where the plurality of claws is closed. The intermediate position may be a position where the plurality of claws grips the workpiece 2703.

The displacement body may be the piston 402 in the air cylinder 102.

As illustrated in FIG. 37 and the like, the setting units 613 and 2513 may set, as the width of the detection range, a width candidate according to a user's operation from among a plurality of the width candidates (examples: 4.0 mm, 8.0 mm). Note that the width may be changed by finer steps according to the operation of the rightward button 3203 or the leftward button 3202 (example: 4.1 mm⇒4.2 mm⇒4.3 mm⇒4.4 mm⇒ . . . ⇒7.9 mm⇒8.0 mm).

As described with reference to FIG. 38, the setting units 613 and 2513 may set both the number and the width of the detection ranges. For example, the number when only the detection range related to the first output signal is set is one. The number when the detection ranges related to the first output signal and the second output signal are set is two. The number when the detection ranges related to the first output signal, the second output signal, and the third output signal are set is three. The number when the detection ranges related to the N output signals are set is N.

### 15. Other Modifications

### (1) External I/F 5060

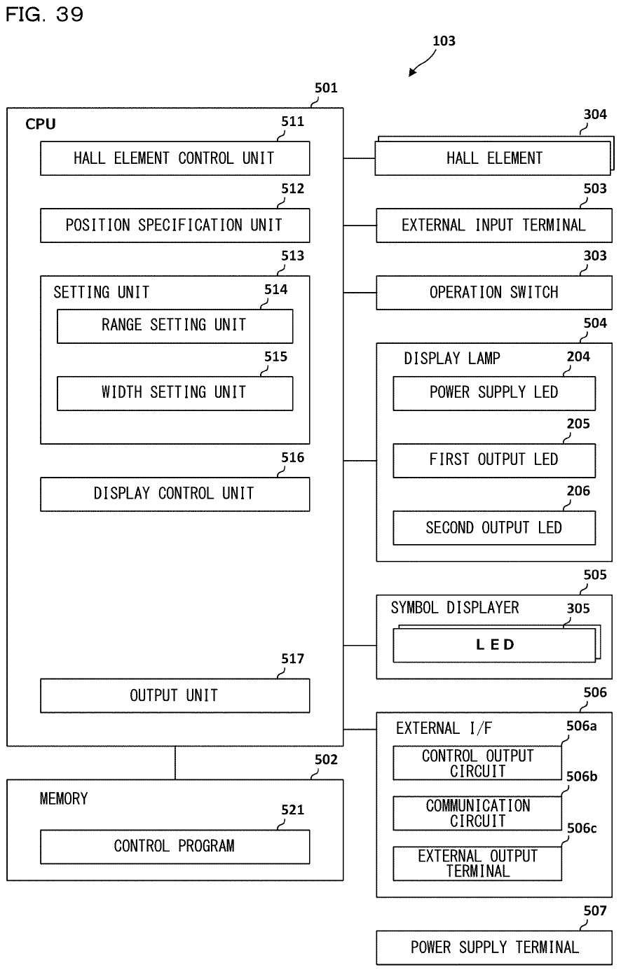

In the control system of the cylinder sensor 103 illustrated in FIG. 5, the output unit 517 outputs the position information indicating the position of the piston 402 specified by the position specification unit 512 to the relay amplifier 104 through the external output terminal 506 and the IO-Link cable 113. However, for example, as illustrated in FIG. 39, the external output terminal 506 may be changed to an external I/F 5060.

In FIG. 39, the external I/F 5060 includes a control output circuit 5060a for sending a control output such as ON/OFF to a programmable logic controller (PLC), a communication circuit 5060b for sending position information, setting information, and the like to the relay amplifier 104 and an I/O link master (not illustrated), and an external output terminal 5060c. Here, one external output terminal 5060c is shared by the control output circuit 5060a and the communication circuit 5060b, but this is merely an example. Two external output terminals 5060c may be provided separately. In this case, the control output circuit 5060a and the communication circuit 5060b can use individual external output terminals 5060c corresponding to each other.

The control output circuit 5060a is a circuit having a function of converting a voltage value (for example, 3.3 V) output by the output unit 517 and indicating a control output into a desired voltage level (for example, 24 V). Furthermore, the communication circuit 5060b is a circuit having a function of converting a voltage value (for example, 3.3 V) output by the output unit 517 and indicating position information or the like into a desired voltage level (for example, 24 V).

Furthermore, in FIG. 39, since the control output circuit 5060a and the communication circuit 5060b are physically realized by one integrated circuit, it is possible to improve the usability of the cylinder sensor 103 while suppressing the manufacturing cost. Furthermore, since the cylinder sensor 103 is often attached to a gripper (chuck) or another movable portion, it is required to reduce the size as much as possible. By physically sharing the control output circuit 5060a and the communication circuit 5060b, the size of the cylinder sensor 103 can be reduced. More specifically, in a case where a threshold or the like is set for the cylinder sensor 103, the relay amplifier 104 is connected to the cylinder sensor 103. At this time, the cylinder sensor 103 can communicate with the relay amplifier 104 by the communication circuit 5060b of the external I/F 5060. On the other hand, in a case where the control output is transmitted to the PLC, the relay amplifier 104 may be detached from the cylinder sensor 103, and the cylinder sensor 103 and the PLC may be directly connected. At this time, the cylinder sensor 103 can transmit the control output to the PLC by the control output circuit 5060a of the external I/F 5060.

### (2) I/O Link Master 1041

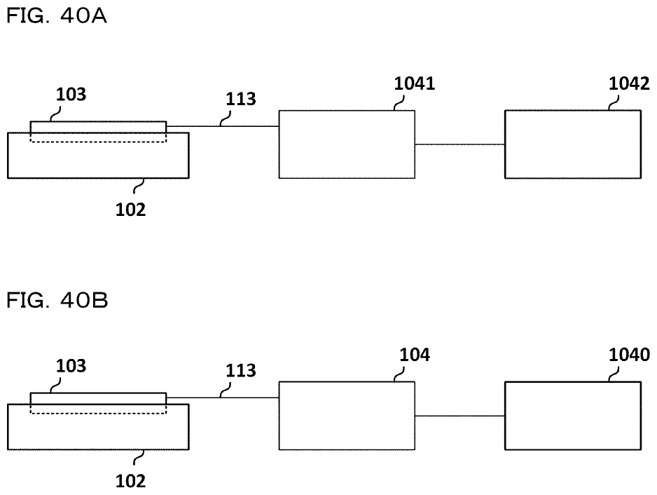

In the position detection sensor 100 illustrated in FIG. 1, an example in which the cylinder sensor 103 is connected to the valve system 101 via the relay amplifier 104 has been described. The present invention is not limited thereto, and for example, as illustrated in FIG. 40A, the cylinder sensor 103 can also be connected to the PLC 1042 via the I/O link master 1041.

The I/O link master 1041 functions as a so-called data relay apparatus that connects a sensor and an actuator disposed at a position away from the PLC 1042 to a network (for example, Ethernet (registered trademark)) to which the PLC 1042 is connected and relays measurement results of the sensor and the actuator to the PLC 1042. The I/O link master 1041 includes a CPU, a storage apparatus, a relay memory (for temporary storage), a communication circuit, and the like in order to realize this relay function. The I/O link master 1041 communicates with the cylinder sensor 103 in accordance with a predetermined communication protocol (for example, IEC61131-9), receives identification information and measurement results, and stores the identification information and the measurement results in a relay memory. The measurement results are cyclically (periodically) received and transferred to the PLC 1042 via the relay memory. When the PLC 1042 performs input/output refresh, the I/O link master 1041 transfers (transmits) the measurement results held in the relay memory to the PLC 1042. Note that a first cycle (collection cycle) in which the I/O link master 1041 acquires information from the cylinder sensor 103 and a second cycle (so-called a control cycle) in which the I/O link master 1041 transmits information to the PLC 1042 may be the same or different. In a case where the first cycle is longer than the second cycle, the number of data acquired by the PLC 1042 becomes relatively small, and the data processing load of the PLC 1042 becomes small. In a case where the first cycle is shorter than the second cycle, the PLC 1042 can acquire the value of the cylinder sensor 103 without missing the value, but the same value is acquired a plurality of times, and the load on the PLC 1042 increases.

In FIG. 40A, the cylinder sensor 103 creates process data (position information and the like) such as position information at every predetermined measurement cycle in accordance with a predetermined output format, and transmits the process data to the I/O link master 1041. As described above, the PLC 1042 communicates with the I/O link master 1041 via an industrial network. The PLC 1042 receives the position information measured by the cylinder sensor 103 via the I/O link master 1041 and stores the position information in a predetermined recording region (data memory, relay device, word device, and the like). The PLC 1042 may execute either cyclic communication for acquiring data from the I/O link master 1041 at every predetermined communication cycle or message communication for acquiring data as a response by transmitting a command.

On the other hand, as illustrated in FIG. 40B, in a case where the cylinder sensor 103 is connected to the relay amplifier 104, the relay amplifier 104 may be connected to a mobile battery 1040. In this case, the external I/F 5060 (communication circuit 5060b) of the cylinder sensor 103 described above communicates with the relay amplifier 104.

In a case where the cylinder sensor 103 is connected to the PLC 1042 (via the I/O link master 1041) as illustrated in FIG. 40A, the control output circuit 5060a of the external I/F 5060 of the cylinder sensor 103 functions. On the other hand, in a case where the cylinder sensor 103 is connected to the relay amplifier 104 as illustrated in FIG. 40B, the communication circuit 5060b of the external I/F 5060 of the cylinder sensor 103 functions. In this manner, by sharing the external I/F 5060, the cylinder sensor 103 can be downsized. Furthermore, as described above, by making the control output circuit 5060a and the communication circuit 5060b physically the same circuit, it is possible to contribute to further downsizing of the cylinder sensor 103.

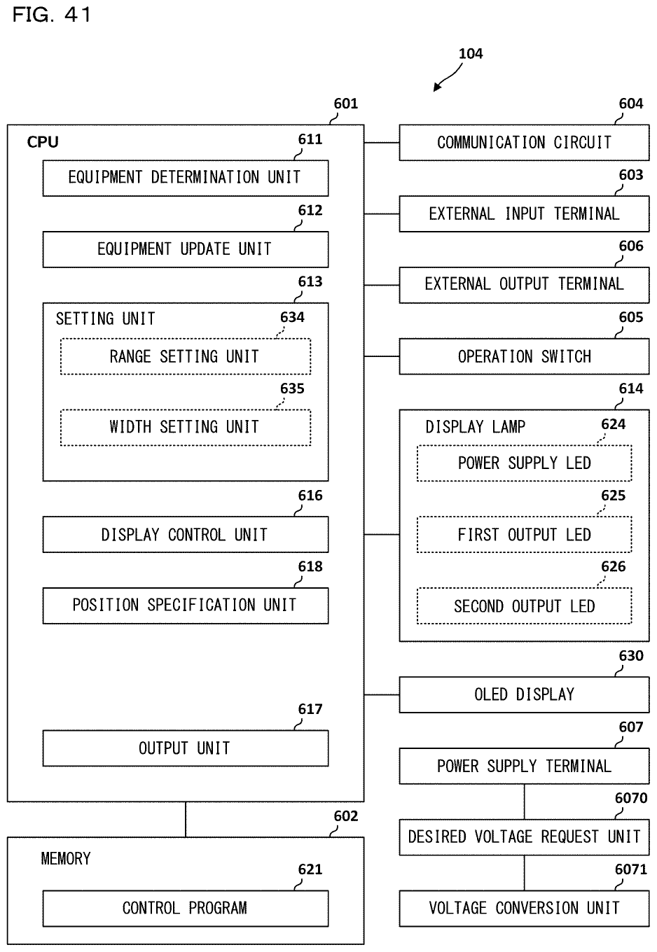

Here, as illustrated in FIG. 40B, the relay amplifier 104 may be connected to the mobile battery 1040. The relay amplifier 104 may include, for example, a desired voltage request unit 6070 and a voltage conversion unit 6071 as illustrated in FIG. 41. The desired voltage request unit 6070 requests a desired voltage (for example, 5 V) from the mobile battery 1040. In response to this request, the mobile battery 1040 supplies a desired voltage (predetermined voltage) to the relay amplifier 104. Furthermore, the voltage conversion unit 6071 has a function of converting the voltage supplied from the mobile battery 1040 into an optimum voltage in order to supply the voltage to the cylinder sensor 103. The relay amplifier 104 can also function as a power supply for communication.

### (3) Abnormality Processing

Next, as another modification, abnormality processing in a case where the cylinder sensor 103 is detached from the relay amplifier 104 and then the cylinder sensor 103 is reconnected to the relay amplifier 104 will be described.

First, a method of judging that the cylinder sensor 103 is connected to the relay amplifier 104 will be described. In order to cause the cylinder sensor 103 to recognize that it is connected to the relay amplifier 104 and in order to perform communication using an output line, the relay amplifier 104 applies a pulse of a specific time to the cylinder sensor 103 via the output line, thereby causing the cylinder sensor 103 to transition to a communication mode. Thereafter, communication is performed from a relay amplifier 104 side, so that the cylinder sensor 103 returns a reply and communication becomes possible.

Here, in a case where the cylinder sensor 103 is detached from the relay amplifier 104, it is assumed to be a communication error in a case where there is no response from the cylinder sensor 103 within a certain time with respect to the transmission from the relay amplifier 104 to the cylinder sensor 103. Transmission from the relay amplifier 104 to the cylinder sensor 103 may be retried a plurality of times until it is judged that a communication error has occurred.

Next, processing in a case where the cylinder sensor 103 is detached from the relay amplifier 104 and then reconnected will be described. For example, the following processing methods are conceivable. Pattern 1) In order to recover the communication, the cylinder sensor 103 is transitioned to the communication mode by applying a pulse of a specific time from the relay amplifier 104. Thereafter, the cylinder sensor 103 communicates with the relay amplifier 104 to enable transmission and reception. Pattern 2) The cylinder sensor 103 is caused to transition to the communication mode by a certain user operation (for example, a button operation of the relay amplifier 104) without attempting to automatically recover the communication from the relay amplifier 104.

Examples of another abnormality processing include a detection error of the magnetic flux density. Since a threshold of the magnetic flux density is held on a cylinder sensor 103 side, it may be determined whether or not the magnetic flux density detected by the cylinder sensor 103 is within a predetermined threshold range, and the determination result may be transmitted to the relay amplifier 104.

The invention is not limited to the above embodiments, and various modifications and changes can be made within the scope of the gist of the invention.

What is claimed is:

1. A position detection sensor configured to detect a position of a displacement body movable in parallel with a first direction, the position detection sensor comprising:
a detection device configured to generate a detection signal according to a position of a magnet provided on the displacement body;
a position specification unit configured to specify a position of the displacement body in the first direction on a basis of the detection signal generated by the detection device;
a determination unit configured to generate determination information on a basis of a position of the displacement body along the first direction specified by the position specification unit and detection ranges set in advance; and
a setting unit configured to be able to adjust positions of a first region and a second region set as the detection ranges and be able to adjust at least one of a number or a width of the detection ranges.

2. The position detection sensor according to claim 1, further comprising a display unit configured to display a position of the displacement body along the first direction specified by the position specification unit and the detection ranges.

3. The position detection sensor according to claim 2, wherein the display unit graphically displays the position of the displacement body and the detection ranges.

4. The position detection sensor according to claim 2, further comprising:
a first housing configured to accommodate the detection device, the position specification unit, and the determination unit; and
a second housing including the setting unit,
wherein the display unit is provided in the second housing.

5. The position detection sensor according to claim 4, wherein the second housing includes a housing of a relay apparatus connected to the first housing via a cable and also connected to, via another cable, a control apparatus configured to control the displacement body.

6. The position detection sensor according to claim 4, wherein the display unit includes a display panel connected to a specific communication port provided in a control apparatus configured to control the displacement body.

7. The position detection sensor according to claim 1, further comprising an output unit configured to output a predetermined output signal when a position of the displacement body is included in each of the detection ranges,
wherein the setting unit sets a threshold and the width for defining the detection range.

8. The position detection sensor according to claim 7, wherein
the setting unit sets, as the detection ranges,
the first region for detecting whether or not the displacement body exists at a first position within a displacement range,
the second region for detecting whether or not the displacement body exists at a second position within the displacement range, and
a third region for detecting whether or not the displacement body exists at an intermediate position between the first position and the second position.

9. The position detection sensor according to claim 8, wherein
the displacement body includes a plurality of claws provided on a chuck and configured to grip a workpiece,
the first position includes a position where the plurality of claws is opened,
the second position includes a position where the plurality of claws is closed, and
the intermediate position includes a position where the plurality of claws grips the workpiece.

10. The position detection sensor according to claim 1, wherein the displacement body includes a piston in an air cylinder.

11. The position detection sensor according to claim 1, wherein the setting unit sets, as the width of the detection ranges, a width candidate according to an operation of a user from among a plurality of the width candidates.

12. The position detection sensor according to claim 1, wherein the setting unit sets both the number and the width of the detection ranges.
